(19) United States
(12) Patent Application Publication
(10) Pub. No.: US 2004/0004498 A1
(43) Pub. Date: Jan. 8, 2004

(54) Signal transmission method, signal transmission system, logic circuit, and liquid crystal drive device

(76) Inventor: Tomoaki Nakao, Yamatokoriyama-shi (JP)

Correspondence Address: Harness, Dickey & Pierce, P.L.C., P.O.Box 8910, Reston, VA, 20195, US

(21) Appl. No.: 10/609,603

(22) Filed: Jul. 1, 2003

(30) Foreign Application Priority Data
Jul. 2, 2002 (JP) 2002-193917

(51) Int. Cl. H03K 19/096

(52) U.S. Cl. 326/95

(57) ABSTRACT

A sending LSI of a signal transmission system is provided with a synthesizing section for producing a multivalued logic signal by synthesizing a clock signal with a data signal in sync with the clock signal. In the meantime, a receiving LSI of the signal transmission system is provided with a separation section for separating the multivalued logic signal, which has been transmitted from the sending LSI, into the original clock signal and data signal. With this arrangement, it is possible to eliminate the constraint of a setup/hold period in the receiving end, without providing complicated synchronizing circuits such as a PLL circuit in the logic circuit of the receiving end.

### FIELD OF THE INVENTION

The present invention relates to a signal transmission method, signal transmission system, and logic circuit, for transmitting logical data (digital signal) in sync with a clock signal from one logic circuit to the other logic circuit, and also relates to a liquid crystal drive device using them.

### BACKGROUND OF THE INVENTION

FIG. 20 illustrates a conventional art for transmitting a data signal as logical data in sync with a clock signal, from one logic circuit to the other logic circuit.

In this arrangement, from a sending LSI (Large Scale Integrated Circuit) 100 to a receiving LSI 101, a clock signal and a data signal as logical data in sync with the clock signal are transmitted through different transmission lines. Although a single data signal and a single clock signal are transmitted in the case of FIG. 20, it is possible to transmit a plurality of clock signals and a plurality of data signals. At any rate, this conventional art is arranged in such a manner that, by the sending LSI 100, a clock signal is sent through a transmission line exclusively for the clock signal, and a data signal is sent through a transmission line exclusively for the data signal.

The receiving LSI 101 includes a latch circuit 102 synchronized with the clock signal, which latches the data signal, so that the data signal received by the latch circuit 102 is fed to the receiving LSI 101. This conventional art has been commonly used for various kinds of logic circuits.

FIG. 21 illustrates another conventional art for transmitting a data signal in sync with a clock signal, from one logic circuit to the other logic circuit.

In this arrangement, only a data signal is transmitted from a sending LSI 103 to a receiving LSI 104. The receiving LSI 104 includes a PLL (Phase Locked Loop) circuit 105, and in this PLL circuit 105, a clock signal is self-generated from the data signal.

The PLL circuit 105 includes an edge detection circuit 106, a phase comparison circuit 107, and a voltage controlled oscillation circuit 108. A clock signal with a certain cycle is self-generated in the voltage controlled oscillation circuit 108. An edge (rise or drop) of this clock signal and an edge (variable point) of a received data signal detected in the edge detection circuit 106 are supplied to the phase comparison circuit 107, then subjected to a timing check. By its voltage value, in accordance with the result of the timing check, a frequency of the voltage controlled oscillation circuit 108 is controlled, so that a clock signal in sync with the edge of the received data signal is generated. Subsequently, being identical with the case of the circuit in FIG. 20, the data signal is latched in the latch circuit 102, in accordance with the self-generated clock signal. This conventional art has been commonly used for various kinds of logic circuits.

However, the arrangement in FIG. 20, in which the clock signal and data signal are transmitted from the sending LSI 100 to the receiving LSI 101 through different transmission lines, has such problems that speeding up the clock signal is difficult and the transmission lines cannot be elongated so much, even though these modifications will be inevitably required in future.

That is to say, when a clock signal and a data signal are transmitted through different transmission lines, it is necessary to properly design a timing, in order to provide a sufficient setup/hold period between the clock signal and data signal. An allowable setup/hold period shortens as the speed of the clock signal increases and the frequency becomes higher. As a result, a design margin of the timing is narrowed, causing the designing of the timing to be difficult.

As illustrated in FIG. 22(a), when transmitted from the sending LSI 100 to the receiving LSI 101, a data signal and a clock signal are delayed in the process of passing through the transmission lines. The length of this delay is, for instance, 1 ns. In this case, provided that both signals are delayed for 1 ns, the signals are still properly timed so that no problems are caused. However, because of the variation between the transmission lines caused in the manufacturing process, the delay time of the data signal is different from the delay time of the clock signal. This variation between the transmission lines is unavoidable.

For instance, provided that the variation between the transmission lines is in the range of 10%, the delay time varies in the range of 1 ns±0.1 ns. In this case, the timing difference between the signals is ±0.2 ns at the maximum (i.e. in the worst case). The margin of the timing has to be designed to be longer than 0.2 ns, in order to certainly acquire the data signal at the edge of the clock signal even when the timing difference between the signals is at the maximum, ±0.2 ns. Thus, if the speedup of the clock signal further proceeds in future, it becomes impossible to design the margin of the timing to be longer than the maximum difference (±0.2 ns in the example above).

The same is equally true of the elongation of the transmission lines. As FIG. 22(b) illustrates, because the distance between the sending LSI 100 and the receiving LSI 101 is longer than the distance in the case of FIG. 22(a). As the respective transmission lines for transmitting the data signal and the clock signal get longer, the signals are further delayed. In this example, for instance, the length of this delay is 10 ns. As a matter of course, provided that the signals are both delayed for 10 ns, there is no timing difference between the signals and hence no problems are caused. However, as described above, because of the variation between the transmission lines caused in the manufacturing process, the delay time of the data signal is different from the delay time of the clock signal.

The variation is consistent regardless of the length of the transmission line. On this account, provided that the variation between the transmission lines is in the range of 10%, the delay time varies in the range of 10 ns±1 ns, and the timing difference between the signals is ±2 ns at the maximum (i.e. in the worst case). When the timing difference between the signals is such a large amount, it is not possible to acquire the data signal at a proper edge of the clock signal, and hence the data signal may be acquired at an inappropriate edge of the clock signal.

In the meantime, there is no timing difference between the signals in the arrangement of FIG. 21, in which the clock signal is not transmitted from the sending LSI 103 so that only the data signal is transmitted to the receiving LSI 104, and the clock signal in accordance with the data signal is generated in the PLL circuit 105 on the side of the receiving LSI 104.

However, since the PLL circuit 105 is necessarily included, the size and power consumption of the receiving LSI 104 inevitably increase. Further, to properly synchronize the PLL circuit 105, the data signal to be transmitted has to include variable points at constant time intervals. For this reason, when a data signal with small variations is transmitted, a process of adding variable points for detecting synchronization has to be additionally provided.

### SUMMARY OF THE INVENTION

The present invention is done to solve the above-described problems, so that the objective of the present invention is to provide solutions such as a signal transmission system which can eliminate the constraint of a setup/hold period in a receiving end without including complicated synchronizing circuits such as a PLL circuit in a logic circuit of the receiving end, when a logic data signal in sync with a clock signal is transmitted from one logic circuit to the other logic circuit.

To solve this objective, the signal transmission method in accordance with the present invention is characterized in that, when a logic data signal in sync with a clock signal is transmitted from a logic circuit to another logic circuit, in a sending end, a multivalued logic signal is synthesized from the clock signal and the logic data signal and outputted, and in a receiving end, the multivalued logic signal is separated into the clock signal and the logic data signal.

According to this arrangement, the clock signal and logic data signal are synthesized and transmitted through a single transmission line. Thus, it is possible to eliminate the timing difference between the clock signal and logic data signal, which is caused due to such a reason that the clock signal and logic data signal are transmitted through different transmission paths.

For this reason, it is possible to eliminate the constraint of a setup/hold period in a receiving end without including complicated synchronizing circuits such as a PLL circuit in a logic circuit of the receiving end, and this makes it possible to accommodate to further speedup of a clock signal and elongation of a transmission path.

The logic circuit of the present invention, for transmitting one clock signal and one or more logic data signal(s) in sync with said one clock signal from a logic circuit to another logic circuit, is characterized by comprising: at least one synthesizing means for synthesizing said one clock signal with said one or more logic data signal(s) so as to produce one multivalued logic signal.

With this arrangement, since the synthesizing means synthesizes one clock signal with one or more logic data signal(s) in sync with said one clock signal so as to produce one multivalued logic signal, it is possible to eliminate the timing difference between the clock signal and the logic data signal(s) transmitted using the logic circuit, which is caused due to such a reason that the clock signal and the logic data signal(s) are transmitted through different transmission paths.

On this account, as already described in relation to the signal transmission method, the logic circuit is adopted as a sending logic circuit for sending a clock signal and a logic data signal and combined with a logic circuit (described later) suitable for a receiving end of the present invention, and this arrangement makes it possible to accommodate to further speedup of a clock signal and elongation of a transmission path.

Note that, when one clock signal is synthesized with a plurality of logic data signals, the efficiency of transmission of the logic data signal is improved so as to be better than the case of synthesizing one clock signal and one logic data signal.

The logic circuit of the present invention is characterized by comprising at least one separation means for separating a multivalued logic signal, which is produced by synthesizing one clock signal with one or more logic data signal(s) in sync with said one clock signal and is transmitted from another logic circuit, into said one clock signal and said one or more logic data signal(s).

With this arrangement, since one multivalued logic signal synthesized from one clock signal and one or more logic data signal(s) is separated into the original one clock signal and the original one or more logic data signal(s) so that it is possible to eliminate the timing difference between the clock signal and the logic data signal(s) transmitted using the logic circuit, which is caused due to such a reason that the clock signal and the logic data signal(s) are transmitted through different transmission paths.

As a result, as already described in relation to the signal transmission method, the logic circuit is adopted as a receiving logic circuit for receiving a clock signal and a logic data signal and combined with the above-described logic circuit suitable for the sending end of the present invention, and this arrangement makes it possible to accommodate to further speedup of a clock signal and elongation of a transmission path.

The signal transmission method of the present invention is characterized by comprising the above-mentioned logic circuit of the present invention as a sending logic circuit and the above-mentioned logic circuit of the preset invention as a receiving logic circuit.

As in the foregoing description, this arrangement is arranged so that the clock signal and logic data signal are synthesized and transmitted through a single transmission line, and hence it is possible to eliminate the timing difference between the clock signal and the logic data signal, which is caused due to such a reason that the clock signal and the logic data signal are transmitted through different transmission paths.

Consequently, it is possible to eliminate the constraint of a setup/hold period in a receiving end without including complicated synchronizing circuits such as a PLL circuit in a logic circuit of the receiving end, and this makes it possible to accommodate to further speedup of a clock signal and elongation of a transmission path.

The liquid crystal drive device of the present invention, comprising: a control circuit for outputting at least one control signal(s) including a clock signal and at least one digital display data signal(s); and a source driver circuit for receiving said at least one control signal(s) and said at least one digital display data signal(s), which have been outputted from the control circuit, is characterized in that, the logic circuit of the present invention, which is the sending logic circuit, is adopted as the control circuit, and the logic circuit of the present invention, which is the receiving logic circuit, is adopted as the source driver circuit.

Drive frequencies of liquid crystal drive devices are on the rise due to the increase of the size of liquid crystal panels. Further, in response to requirements such as narrowing the frame, aspect ratios of semiconductor devices such as a source driver circuit constituting a liquid crystal device further increase, while transmission lines connecting semiconductor devices also get longer.

Thus, adopting the signal transmission system using the logic circuits of the present invention which realize the above-described signal transmission method of the present invention, it is possible to realize an excellent liquid crystal drive device which can accommodate to speedup of drive frequencies and elongation of a transmission path which are due to the increase of the size of liquid crystal panels.

For a fuller understanding of the nature and advantages of the invention, reference should be made to the ensuing detailed description taken in conjunction with the accompanying drawings.

### BRIEF DESCRIPTION OF THE DRAWINGS

FIG. 1, in accordance with an embodiment of the present invention, is a schematic block diagram illustrating an arrangement of a signal transmission system in which a data signal and a clock signal are synthesized, and as a multivalued logic signal, transmitted from a sending LSI to a receiving LSI.

FIGS. 2(a)-2(c) are waveform charts, illustrating respective signals for the signal transmission system of FIG. 1.

FIG. 3 is a circuit diagram, illustrating an arrangement of synthesizing section of the signal transmission system of FIG. 1.

FIG. 4 is a circuit diagram, illustrating an arrangement of a clock detection circuit and a data detection circuit, provided in a separation section of the signal transmission system of FIG. 1.

FIG. 5, in accordance with another embodiment of the present invention, is a schematic block diagram illustrating an arrangement of a signal transmission system in which a data signal and a clock signal are synthesized, and as a multivalued logic signal, transmitted from a sending logic circuit to a receiving logic circuit.

FIG. 6 is a circuit diagram, illustrating an arrangement of synthesizing section of the signal transmission system of FIG. 5.

FIG. 7 is a circuit diagram, illustrating, along with a current mirror circuit, an arrangement of a clock detection circuit and a data detection circuit, provided in a separation section of the signal transmission system of FIG. 5.

FIG. 8, in accordance with a further embodiment of the present invention, is a schematic block diagram illustrating an arrangement of a signal transmission system in which a data signal and a clock signal are synthesized, and as a multivalued logic signal, transmitted from a sending logic circuit to a receiving logic circuit.

FIGS. 9(a)-9(c) are waveform charts, illustrating respective signals for the signal transmission system of FIG. 8.

FIG. 10 is a circuit diagram, illustrating an arrangement of a synthesizing section of the signal transmission system of FIG. 8.

FIG. 11, in accordance with yet another embodiment of the present invention, is a schematic block diagram illustrating an arrangement of a signal transmission system in which a data signal and a clock signal are synthesized, and as a multivalued logic signal, transmitted from a sending logic circuit to a receiving logic circuit.

FIG. 12, in accordance with yet another embodiment of the present invention, is a schematic block diagram illustrating an arrangement of a signal transmission system in which a data signal and a clock signal are synthesized, and as a multivalued logic signal, transmitted from a sending logic circuit to a receiving logic circuit.

FIG. 13, in accordance with yet another embodiment of the present invention, is a view illustrating an arrangement in which a sending logic circuit and a receiving logic circuit are mounted on a single LSI.

FIG. 14, in accordance with still another embodiment of the present invention, is a block diagram illustrating a typical arrangement of a liquid crystal display device provided with a liquid crystal drive device.

FIG. 15 is an equivalent circuit diagram, illustrating an overall arrangement of a liquid crystal panel of the liquid crystal display device.

FIG. 16 is a block diagram, illustrating a conventional source driver circuit of the liquid crystal drive device of the foregoing liquid crystal display device, arranged in such a manner that display data and a clock signal are transmitted through different transmission lines.

FIG. 17 is a block diagram, illustrating a source driver circuit of the liquid crystal drive device of the foregoing liquid crystal display device, adopting such an arrangement that display data and a clock signal are synthesized, and as a multivalued logic signal, transmitted through a single transmission line.

FIG. 18 is a block diagram, illustrating substantial parts of a source driver circuit and a control circuit provided in the liquid crystal drive device of the foregoing liquid crystal display device, the source driver circuit and the control circuit adopting such an arrangement that display data and a clock signal are synthesized, and as multivalued logic signals, transmitted through a single transmission line.

FIG. 19 is a block diagram, illustrating an arrangement of an input latch circuit provided in the source driver circuit of FIG. 17.

FIG. 20 is a schematic block diagram, illustrating an arrangement of a conventional signal transmission system in which a data signal and a clock signal are transmitted from a sending logic circuit to a receiving logic circuit, through different transmission lines.

FIG. 21 is a schematic block diagram, illustrating an arrangement of a conventional signal transmission system in which only a data signal is transmitted from a sending logic circuit to a receiving logic circuit, and a clock signal is generated in a receiving end.

FIGS. 22(a) and 22(b) are views for describing the occurrence of timing difference between a clock signal and a data signal, when the data signal and the clock signal are transmitted from a sending logic circuit to a receiving logic circuit through different transmission lines.

### DESCRIPTION OF THE EMBODIMENTS

A signal transmission method of the present invention is characterized in that, when transmitting a logic data signal in sync with a clock signal from one logic circuit to the other logic circuit, the clock signal and the logic data signal are synthesized in the sending end so as to be outputted as a multivalued logic signal, and in the receiving end, the multivalued logic signal is separated into the clock signal and the logic data signal.

The following will describe (i) a logic circuit in the sending end, (ii) a logic circuit in the receiving end, and (iii) a signal transmission system including these logic circuits, these arrangements (i)-(iii) being provided for realizing the above-described signal transmission method, and (iv) a liquid crystal drive device adopting the signal transmission method of the present invention.

[First Embodiment]

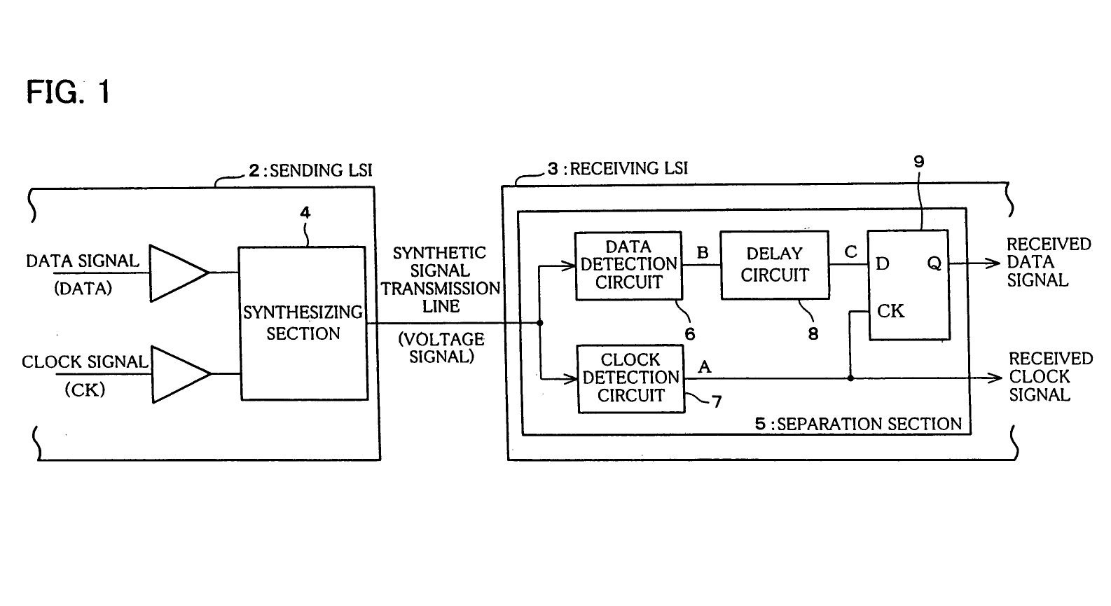

Referring to FIGS. 1-4, an embodiment in accordance with the present invention will be described below.

FIG. 1 is a block diagram, illustrating an overall arrangement of a signal transmission system of the present embodiment. The figure shows an example that a sending logic circuit and a receiving logic circuit, constituting a signal transmission system, are mounted on different LSIs. These logic circuits may be mounted on a single LSI.

A sending LSI 2 on which the sending logic circuit is mounted transmits a clock signal and a logic data signal (hereinafter, will be simply referred to as data signal) in sync with the clock signal to a receiving LSI 3 on which the receiving logic circuit is mounted. The receiving LSI 3 receives the clock signal and the data signal in sync with the clock signal, which are transmitted from the sending LSI 2.

In this signal transmission system, it should be noted that the sending LSI 2 is provided with a synthesizing section (first synthesizing means) 4 by which a multivalued logic signal is synthesized from a data signal and a clock signal which are to be transmitted, and also the receiving LSI 3 is provided with a separation section (first separation means) 5 by which the multivalued logic signal transmitted from the sending LSI 2 is separated into the original clock signal and data signal.

With this arrangement, in the sending LSI 2, one multivalued logic signal is (i) synthesized from the data signal and clock signal which are to be transmitted, (ii) outputted to the receiving LSI 3 via a single synthetic signal transmission line, and (iii) in the receiving LSI 3, separated into the original data signal and clock signal.

Although a single data signal is synthesized with a clock signal in the present embodiment, a plurality of data signals may be synthesized with a clock signal, and this will be specifically described in Embodiment 3. Also, the data signal may be multivalued logical data, the values thereof being not less than 3. Further, although in the present embodiment the sending LSI 2 includes a single synthesizing section 4 and the receiving LSI 3 includes a single separation section 5, a plurality of the synthesizing section 4 and a plurality of the separation section 5 may be provided in respective LSIs when a plurality of data signals are to be transmitted. This arrangement will be specifically described in Embodiment 4.

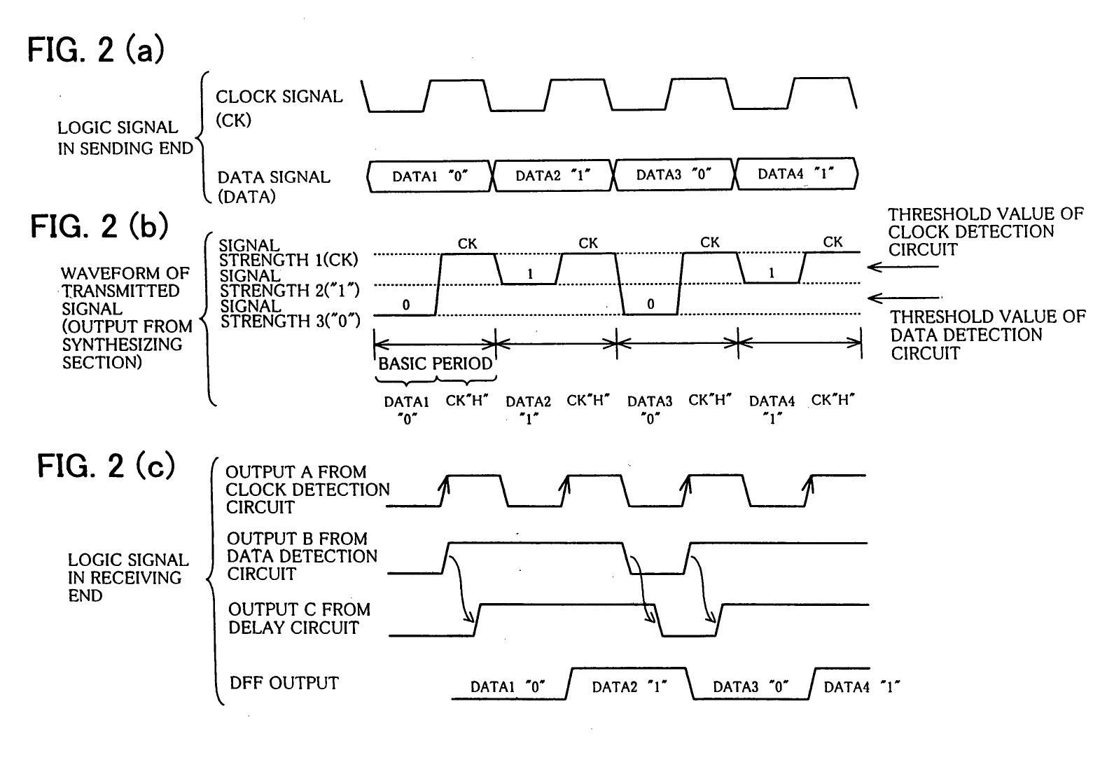

FIGS. 2(a)-2(c) are waveform charts, illustrating respective signals for the above-described signal transmission system. These figures show such an example that a data signal (DATA) to be synthesized with a clock signal (CK) is a binary digital signal, and transmitted as a voltage signal (voltage waveform). The voltage signal is easily realized using a CMOS logic circuit, thereby the circuit design being simplified. The data signal and clock signal may be transmitted as a current signal, and this arrangement will be specifically described in Embodiment 2. In the following descriptions, a logical level “H” of the data signal will be referred to as “1”, and a logical level “L” of the data signal will be referred to as “0”.

FIG. 2(a) shows the binary data signal and binary clock signal which are to be transmitted. To synthesize a single multivalued logic signal from the binary data signal and binary clock signal, the signal strength (voltage in this case) of the multivalued logic signal has to be 3.

Thus, the synthesizing section 4 produces 3 stages of signal strengths. This synthesizing section 4 is arranged in such a manner that a signal strength 1 is always outputted in the second half (“H”) of a basic-rate waveform which is equivalent to one cycle of the clock signal. Meanwhile, in the first half (“L”) of the basic period, the synthesizing section 4 is arranged so as to output a signal strength 2 or a signal strength 3 in accordance with a logical value “1”/“0” of the binary data signal to be synthesized. In the present embodiment, the signal strength 2 is outputted when the data signal has the logical value “1”, and the signal strength 3 is outputted when the data signal has the logical value “0”.

With this arrangement of the synthesizing section 4, as FIG. 2(b) illustrates, when one cycle of the clock signal is divided into the first half and the second half, a signal waveform after the synthesis is a 3-valued logic signal (hereinafter, could be referred to as 3-valued signal at times) which has, in the first half, the signal strength 2 or 3 in accordance with the value “1”/“0” of the binary data signal, while in the second half, always has the signal strength 1.

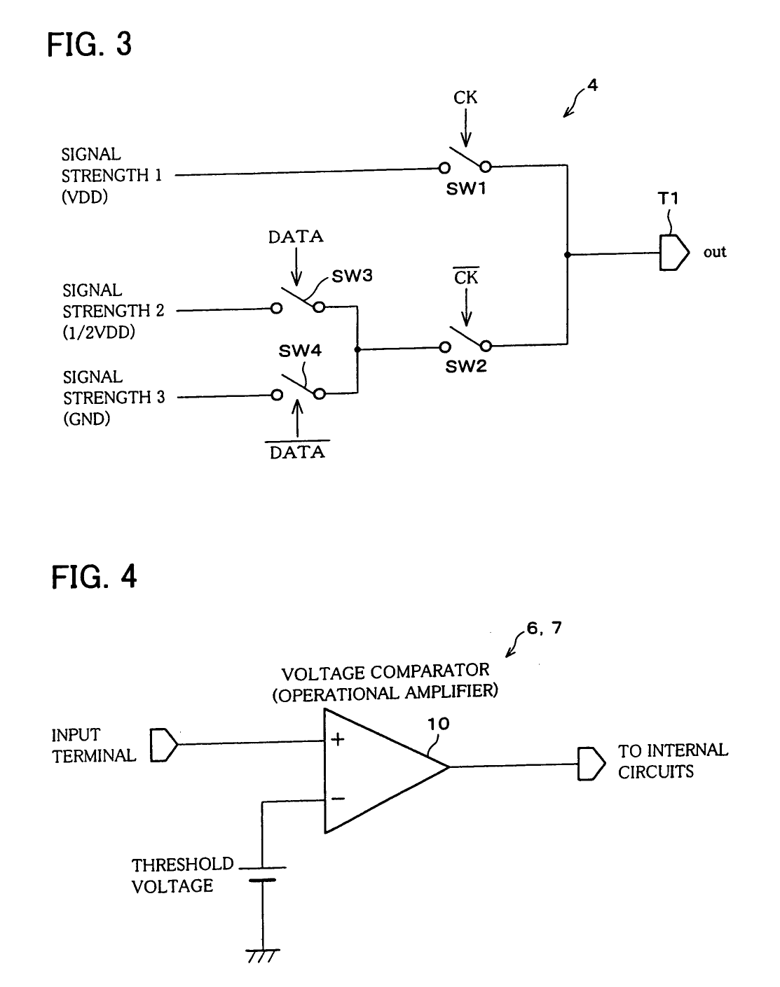

FIG. 3 illustrates an example of this synthesizing section 4 outputting such a 3-valued logic signal. A signal strength 1 (VDD, source of signal strength) is supplied to an output terminal (output section) T1 via a switch SW1, and the switch SW1 turns ON only when the clock signal (CK) is “H”. With this arrangement, an output signal from the output terminal T1 has the signal strength 1 in the second half of a cycle in which the clock signal is “H”.

A signal strength 2 (1/2VDD, source of signal strength) is supplied to the output terminal T1 via switches SW3 and SW2. The switch SW3 turns ON when the data signal (DATA) is “1”, while the switch SW2 turns ON when an inversion of the clock signal (CK with a bar) is “H”, i.e. when the clock signal is “L”. With this arrangement, the output signal from the output terminal T1 has the signal strength 2 in the first half of a cycle in which the clock signal is “L” and also when the data signal is “1”.

A signal strength 3 (GND) is supplied to the output terminal T1 via a switch SW4 and the above-mentioned switch SW2. The switch SW4 turns ON when an inversion of the data signal (DATA with a bar) is “1”, i.e. when the data signal is “0”. With this arrangement, the output signal from the output terminal T1 always has the signal strength 3 in the first half of a cycle in which the clock signal is “L” and also when the data signal is “0”.

In the meantime, the separation section 5 on the side of the receiving LSI 3 is, as illustrated in FIG. 1, including: a clock detection circuit 7 and a data detection circuit 6, both receiving a 3-valued synthetic signal; a delay circuit 8 to which an output (a data detection circuit output, a logical value restoration data signal) B from the data detection circuit 6 is supplied; and a latch circuit 9 to which an output signal (delay circuit output) C from the delay circuit 8 and an output signal (clock detection circuit output) A from the clock detection circuit 7 are supplied.

The clock detection circuit 7 outputs “H” only when the signal strength is 1, and otherwise outputs “L”. Thus, the output signal A from this clock detection circuit 7 is, as illustrated in FIG. 2(c), equivalent to the clock signal (cf. FIG. 2(a)) in the sending LSI 2 before being synthesized to produce the 3-valued signal.

Meanwhile, the data detection circuit 6 outputs “0” only when the signal strength is 3, and otherwise outputs “1”. Thus, as illustrated in FIG. 2(c), the output signal B from this data detection circuit 6 includes a value corresponding to the data signal (cf. FIG. 2(a)) in the sending LSI 2 before being synthesized to produce the 3-valued signal, only when the clock detection circuit output A is “L”, and the output signal B is always “1” when the clock detection circuit output A is “H”.

The delay circuit 8 is provided for causing the data detection circuit output B and clock detection circuit output A to be properly timed. The latch circuit 9 latches the delay circuit output C by means of the clock detection circuit output A.

Here, it is possible to supply the output signal B from the data detection circuit 6 to the latch circuit 9, without modification. However, the edge of the output signal B from the data detection circuit 6 is overlapped with the edge of the output signal A from the clock detection circuit 7, and this overlap of the edges increases the risk of logical malfunction in the latch circuit 9. Thus, the delay circuit 8 is provided, and as in FIG. 2(c), the output signal B from the data detection circuit 6 is delayed for a predetermined period of time so that the delay circuit output C is produced in order to avoid the above-mentioned overlap of the edges.

Since in the latch circuit 9 the delay circuit output C is latched by setting the clock detection circuit output A as a clock signal, the output signal (DFF output) from the latch circuit 9 is, as FIG. 2(c) illustrates, logically equivalent to the data signal (cf. FIG. 2(a)) in the sending LSI 2 before being synthesized to produce the 3-valued signal, and the waveform of the output signal from the latch circuit 9 is also equivalent to the waveform of the data signal. Then along with the restored clock signal (clock detection circuit output A), the output signal from the latch circuit 9 is outputted from the separation section 5.

FIG. 4 illustrates an arrangement of the data detection circuit 6 and the clock detection circuit 7. The data detection circuit 6 and the clock detection circuit 7 both include respective voltage comparators (operational amplifiers) 10. The voltage comparator 10 compares an input voltage with a threshold voltage, and outputs “1” (“H”) when the input voltage is higher than the threshold voltage, or outputs “0” (“L”) when the input voltage is lower than the threshold voltage. In the clock detection circuit 7, a voltage between the signal strengths 1 and 2 is adopted as the threshold voltage (cf. FIG. 2(b)). In the data detection circuit 6, a voltage between the signal strengths 2 and 3 is adopted as the threshold voltage (cf. FIG. 2(b)).

Since the delay circuit 8 and the latch circuit 9 are both conventional arts, no specific examples thereof are provided here.

As described above, the signal transmission system of the present embodiment is arranged in such a manner that, a sending LSI 2 synthesizes, in a synthesizing section 4, a multivalued logic signal from a data signal and a clock signal both to be transmitted, and outputs the multivalued logic signal to a receiving LSI 3 via a single synthetic signal transmission line, and in the receiving LSI 3, the multivalued logic signal having been transmitted is, in the separation section 5, separated into the original clock signal and data signal.

With this arrangement, it is possible to eliminate the timing difference between the clock signal and logic data signal because of the variation between the transmission lines caused in the manufacturing process, the timing difference occurring when these signals are transmitted through different transmission lines. As a result, the receiving LSI 3 can eliminate the constraint of the setup/hold period without including complicated synchronizing circuits such as a PLL circuit in the receiving end, and hence it is possible to obtain a sufficient design margin of the timing even if the speedup of the clock signal further proceeds.

Moreover, as described above, when a sending logic circuit and a receiving logic circuit are mounted on different LSIs 2 and 3, it is necessary to elongate the transmission line. For this reason, when a clock signal and a data signal are transmitted through different transmission lines, the risk of causing the timing difference between the signals increases.

Provided that the signal transmission system of the present embodiment is adopted, even if the transmission line(s) is elongated so that the risk of causing the timing difference between the signals, the timing difference being due to the variation between the transmission lines caused in the manufacturing process, increases, it is possible to acquire the data signal at a predetermined edge of the clock signal, without causing the timing margin to be particularly long.

It is noted that the above-described arrangements of the synthesizing section 4 and the separation section 5 are mere examples, and thus the present invention is not to be limited by these arrangements.

Further, particularly in separation section 5, a delay circuit 8 is provided on the output side of a data detection circuit 6. However, as described above, the delay circuit 8 is provided for upsetting the timing between an output signal B from the data detection circuit 6 and an output signal A from a clock detection circuit 7, in order to avoid the overlap of the edges. Thus, the delay circuit 8 may be, for instance, provided on the output side of the clock detection circuit 7, or alternatively, the delay circuit 8 may be provided on the input side of the data detection circuit 6 or clock detection circuit 7. Moreover, the number of the delay circuit 8 may be more than one. However, when the delay circuit 8 is provided on the input side, a 3-valued signal is also delayed. Thus, the delay circuit 8 has to be an analog signal. On this account, it becomes slightly difficult to properly arrange the delay time.

[Embodiment 2]

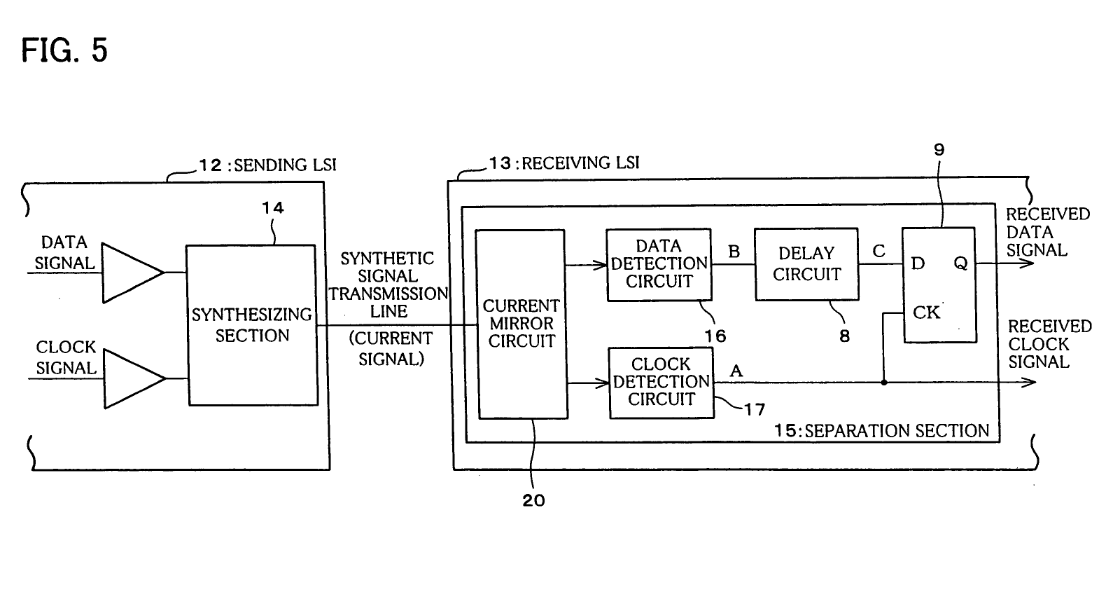

The following will describe another embodiment of the present invention, with reference to FIGS. 5-7. By the way, members having the same functions as those described in Embodiment 1 are given the same numbers, so that the descriptions are omitted for the sake of convenience.

Embodiment 1 is arranged in the following manner. A multivalued logic signal is synthesized in a sending LSI 2 from a data signal and a clock signal which are to be transmitted, and then outputted to a receiving LSI 3, thereby being separated into the original clock signal and data signal. In this arrangement, a voltage signal (voltage waveform) is used as the multivalued logic signal and a voltage value indicates the signal strength.

Voltage signals have such advantages that they makes it possible to easily realize a logic circuit by adopting a CMOS logic circuit and the circuit arrangement is simple. Meanwhile, current signals are also advantageous for such a reason that, since a circuit is easily constructed using a constant current operation of a CMOS device, signal transmission with little voltage amplitude can be realized so that parasitic emissions can be reduced.

In this connection, compared to Embodiment 1, a signal transmission system of the present embodiment is arranged such that, instead of the above-mentioned voltage signal and voltage value, a current signal is used as a multivalued logic signal and the signal strength is indicated by a current value.

In the present embodiment, provided that what are indicated (i) by 3 stages of signal strengths of a 3-valued signal and (ii) by “1”/“0” of a clock signal and a data signal are arranged so as to be identical with those in Embodiment 1, waveforms of respective signals in the present signal transmission system are identical with those of Embodiment 1 described in FIGS. 2(a)-2(c), except that the signal strength is indicated by a current value in place of a voltage value.

Thus, since a current signal is adopted as a multivalued logic signal instead of a voltage signal, to simplify the description, the following only deals with those parts different from the signal transmission system of Embodiment 1.

FIG. 5 illustrates an overall arrangement of a signal transmission system of the present embodiment. As the figure indicates, in a case that a multivalued logic signal is a current signal, a current mirror circuit 20 for generating an output current identical with an input current is additionally provided in a separation circuit 15 of a receiving LSI 13. Further, synthesizing section (first synthesizing means) 14 of a sending LSI 12 and a data detection circuit 16 and a clock detection circuit 17 of a separation section (first separation section) 15 of the receiving LSI 13 are arranged such that the signal strength is indicated by a current value instead of a voltage value.

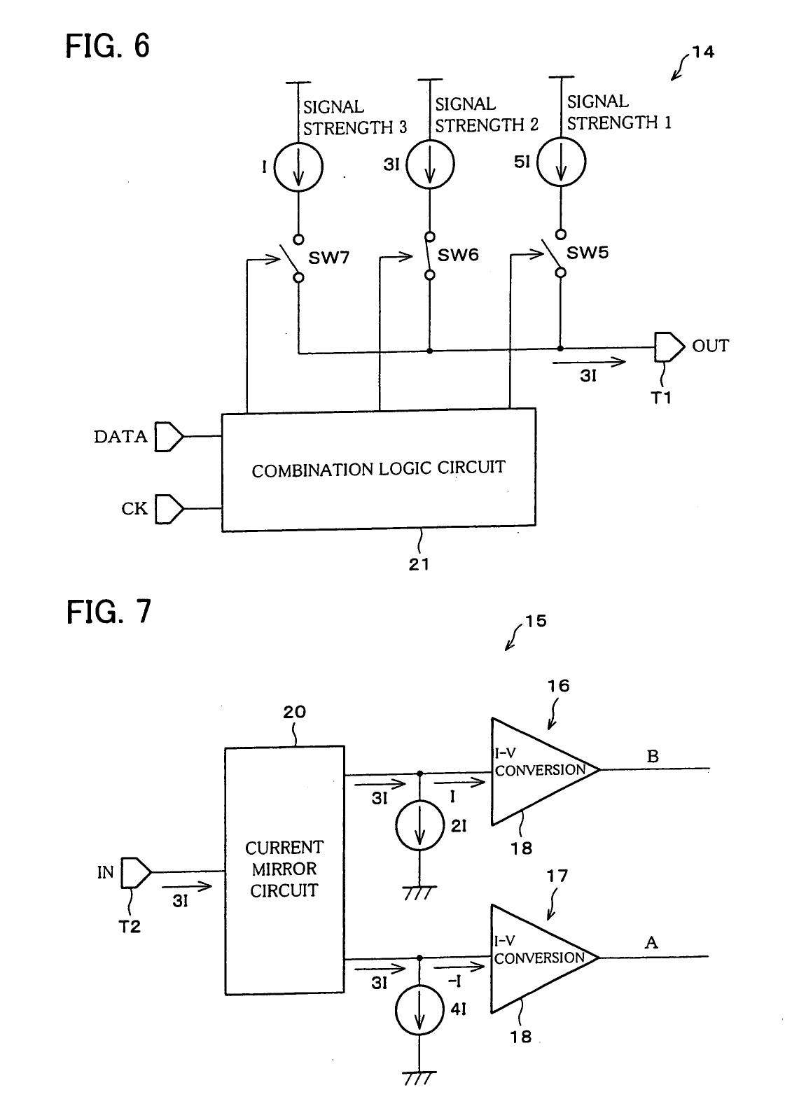

FIG. 6 illustrates an arrangement of the synthesizing section 14 for outputting a 3-valued logic signal which is a current signal. A signal strength 1 (current value 5I, source of signal strength) is supplied to an output terminal T1 via a switch SW5. Similarly, a signal strength 2 (current value 3I, source of signal strength) is supplied to the output terminal T1 via a switch SW6 and a signal strength 3 (current value 1I, source of signal strength) is supplied to the output terminal T1 via a switch SW7.

These switches SW5-SW7 are turned ON or OFF by a combination logic circuit 21. To this combination logic circuit 21, a data signal (DATA) and a clock signal (CK) are supplied.

The combination logic circuit 21 turns ON only the switch SW5 when the clock signal is “H”. On this account, an output signal from the output terminal T1 always has a signal strength 1 in a second half of a cycle in which the clock signal is “H”.

The combination logic circuit 21 turns ON either one of the switches SW6 and SW7 in accordance with “1”/“0” of the data signal, when the clock signal is “L”. More specifically, the switch SW6 is turned ON when the data signal is “1”, while the switch SW7 is turned ON when the data signal is “0”. With this arrangement, in the first half of the cycle in which the clock signal is “L”, the output signal from the output terminal T1 has a signal strength 2 when the data signal is “1”, or has a signal strength 3 when the data signal is “0”. Note that, FIG. 6 illustrates a case when the switch SW6 is turned ON and a current 3I flows into the output terminal T1.

FIG. 7 illustrates an arrangement of the clock detection circuit 17 and the data detection circuit 16 in the separation section 15 on the side of the receiving LSI 3, both of these circuits receiving a 3-valued logic signal which is a current signal via the current mirror circuit 20. FIG. 7 illustrates a case when a current 3I corresponding to the signal strength 2 flows into an input terminal T2.

In this arrangement, both of the data detection circuit 16 and clock detection circuit 17 include respective I-V conversion circuits 18. The I-V conversion circuit 18 outputs, in accordance with the direction of an input current, a logical level “1” (“H”) when the current flows into the I-V conversion circuit 18 or a logical level “0” (“L”) when the current flows out from the I-V conversion circuit 18.

The clock detection circuit 17 outputs “H” only when the signal strength corresponding to the supplied current value is 1, and otherwise outputs “L”. Thus, to the input side of the I-V conversion circuit 18 constituting the clock detection circuit 17, a current value 4I which is between the signal strengths 1 and 2 is supplied as a reference current (cf. FIG. 2(b)).

Thus, a current 1I which is the difference between the reference current 4I and the input current 5I flows into the I-V conversion circuit 18 of the clock detection circuit 17 only when an output current from the current mirror circuit 20 to the clock detection circuit 17 is a current 5I corresponding to the signal strength 1, and hence the I-V conversion circuit 18 of the clock detection circuit 17 outputs a logic level “H”. In other cases, e.g. when an input current 3I or 1I corresponding to the signal strength 2 or 3 flows from the current mirror circuit 20 to the clock detection circuit 17, a current −1I or −3I which is the difference between a reference current 4I and the current 3I or 1I flows into the I-V conversion circuit 18 of the clock detection circuit 17, i.e. the current 1I or 3I flows out from the I-V conversion circuit 18 of the clock detection circuit 17, and for this reason, the I-V conversion circuit 18 of the clock detection circuit 17 outputs a logic level “L”.

Meanwhile, the data detection circuit 16 outputs “0” only when the signal strength of a supplied current value is 3, and otherwise outputs “1”. Thus, to the input side of the I-V conversion circuit 18 constituting the data detection circuit 16, a current value 2I between the signal strengths 2 and 3 is supplied as a reference current (cf. FIG. 2(b)).

Thus, only when an output current from the current mirror circuit 20 to the data detection circuit 16 is the current 1I corresponding to the signal strength 3, the current −1I which is the difference between the reference current 2I and the output current 1I flows into the I-V conversion circuit 18 of the data detection circuit 16, i.e. the current 1I flows out from the I-V conversion circuit 18 of the data detection circuit 16, and for this reason, the I-V conversion circuit 18 of the data detection circuit 16 outputs a logic level “0”.

Also, when the output signal from the current mirror circuit 20 to the data detection circuit 16 is the current 5I or 3I corresponding to the signal strength 1 or 2, the current 3I or 1I which is the difference between the reference current 2I and the output current 5I or 3I flows into the I-V conversion circuit 18 of the data detection circuit 16, and hence the I-V conversion circuit 18 of the data detection circuit 16 outputs a logic level “1”.

The subsequent operations of the data detection circuit 16 and the clock detection circuit 17 on the output side are identical with those of the separation circuit 5 in Embodiment 1 which has been described with reference to FIG. 1.

Although further explanations are omitted here, the present signal transmission system is arranged so as to be basically identical with the signal transmission system of Embodiment 1, except that the multivalued logic signal is a current signal. Thus, a data signal to be synthesized with a clock signal may have values not less than 3, and it is possible to arbitrarily determine where and how many the delay circuit 8 is provided.

[Embodiment 3]

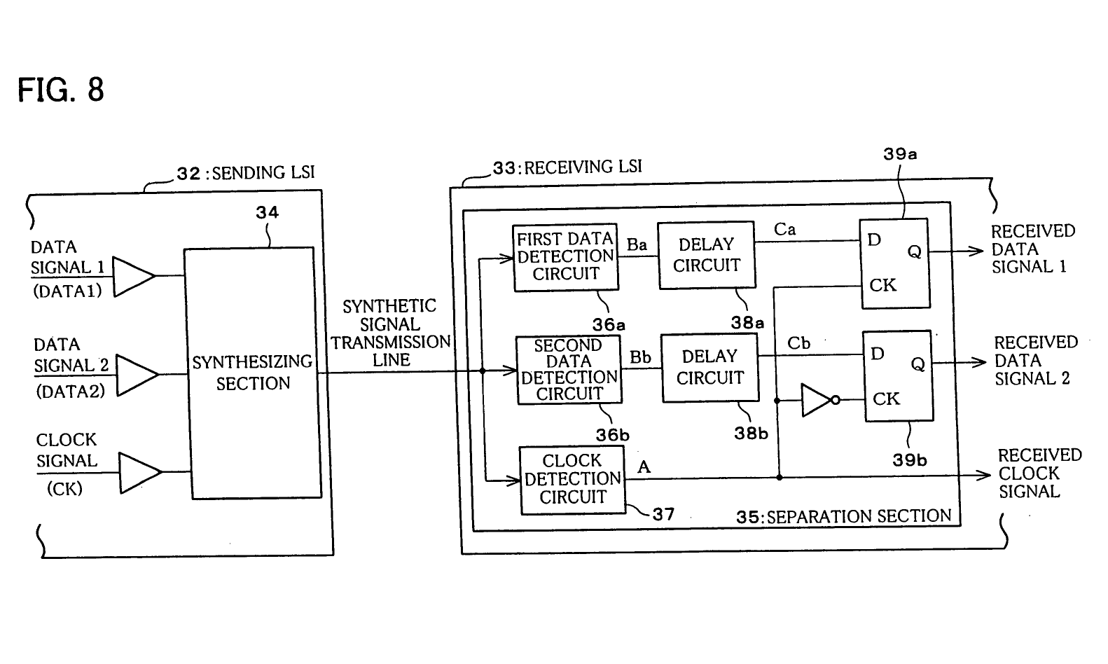

Referring to FIGS. 8-10, a further embodiment of the present invention will be described below. By the way, members having the same functions as those described in Embodiments 1 and 2 are given the same numbers, so that the descriptions are omitted for the sake of convenience.

Embodiments 1 and 2 are arranged in the following manner. A single multivalued logic signal is synthesized from a single data signal and a single clock signal in a sending LSI 2 or 12, and the multivalued logic signal is transmitted to a receiving LSI 3 or 13 via a single synthetic signal transmission line. Then in the receiving LSI 3 or 13, the multivalued logic signal is separated into the original clock signal and data signal.

In contrast, the present embodiment is arranged in such a manner that a multivalued logic signal is synthesized from a plurality of data signals and a single clock signal. Although the present embodiment describes a case when two data signals 1 and 2 each having two logical levels is synthesized with a single clock signal, as described above, the data signal may have not less than 3 levels and the number of data signals to be synthesized may be not less than 3.

A sending LSI 32 on which a sending logic circuit is mounted transmits a clock signal (CK) and a data signal 1 (DATA1) and a data signal 2 (DATA2) both in sync with the clock signal to a receiving LSI 33 on which a receiving logic circuit is mounted. It should be noted that a synthesizing section (second synthesizing means) 34 is provided in the sending LSI 32 so that the data signals 1 and 2 and the clock signal, which are to be transmitted, are synthesized so that a single multivalued logic signal is produced and then outputted.

In the meantime, the receiving LSI 33 receives the clock signal and the data signals 1 and 2 both in sync with the clock signal, and it should be noted that a separation section (second separation means) 35 is provided in the receiving LSI 33 so that the multivalued logic signal, synthesized from the data signals 1 and 2 and the clock signal, is received and then separated into the original data signals 1 and 2 and the original clock signal.

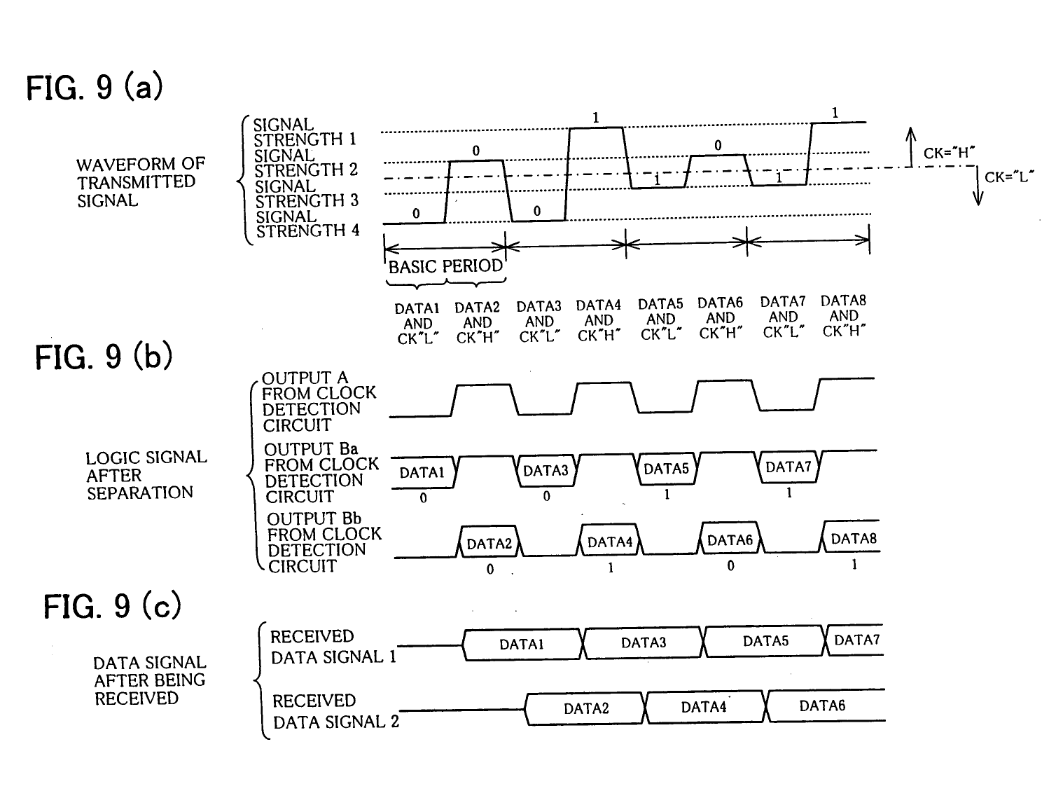

FIGS. 9(a)-9(c) are waveform charts illustrating respective signals for the present signal transmission system. FIGS. 9(a)-9(c) illustrate a case when the data signals 1 and 2 to be synthesized with the clock signal (CK) are binary digital signals, and transmitted as a voltage signal (voltage waveform). Although the present embodiment describes such a case that the multivalued signal is a voltage signal as in Embodiment 1, the signal may be a current signal as in Embodiment 2. To synthesize two binary data signals with a single binary clock signal so as to produce a single multivalued logic signal, four stages of signal strengths (voltages in this case) are required.

Thus, the synthesizing section 34 has four stages of signal strengths. In the first half (“L”) of a basic period waveform equivalent to one cycle of the clock signal, the synthesizing section 34 outputs a signal strength 3 or 4 in accordance with a logical value “1”/“0” of the binary data signal 1 to be synthesized. In this case, the signal strength 3 is outputted when the data signal 1 is “1”, while the signal strength 4 is outputted when the data signal 1 is “0”.

In the second half (“H”) of the basic period waveform, the synthesizing section 34 outputs the signal strength 1 or 2 in accordance with the logical value “1”/“0”, of the binary data signal 2 to be synthesized. That is to say, the signal strength 1 is outputted when the data signal 2 is “1”, while the signal strength 2 is outputted when the data signal 2 is “0”.

With this arrangement of the synthesizing section 34, the signal waveform after the synthesis has a value as illustrated in FIG. 9(a). Namely, provided that a cycle of the clock signal is divided into a first half and a second half, in the first half, the value of the signal waveform is either the signal strength 3 or the signal strength 4 in accordance with the value “1”/“0” of the binary data signal 1, while in the second half, the value of the signal waveform is either the signal strength 1 or the signal strength 2 in accordance with the value “1”/“0” of the binary data signal 2.

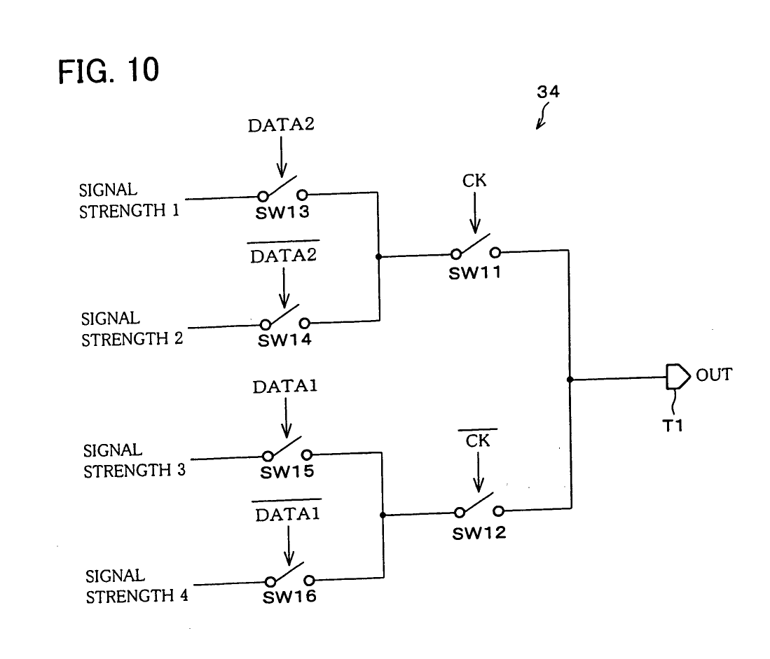

FIG. 10 illustrates an arrangement of the above-mentioned synthesizing section 34 outputting such a 4-valued logic signal. A signal strength 1 is supplied to the output terminal T1 via switches SW13 and SW11. The switch SW13 turns ON when the data signal 2 is “1”, and the switch SW11 turns ON when the clock signal is “H”. With this arrangement, in the second half of a cycle in which the clock signal is “H” and also when the data signal 2 is “1”, an output signal from the output terminal T1 has the signal strength 1.

Meanwhile, a signal strength 2 is supplied to the output terminal T1 via switches SW14 and SW11. The switch SW14 turns ON when an inversion of the data signal 2 (DATA2 with a bar) is “1”, i.e. when the data signal 2 is “0”, while the switch SW11 turns ON when the clock signal is “H”. With this arrangement, in the second half of a cycle in which the clock signal is “H” and also when the data signal 2 is “0”, an output signal from the output terminal T1 has the signal strength 2.

A signal strength 3 is supplied to the output terminal T1 via switches SW15 and SW12. The switch SW15 turns ON when the data signal 1 is “1”, while the switch SW12 turns ON when an inversion of the clock signal (CK with a bar) is “H”, i.e. when the clock signal is “L”. With this arrangement, in the first half of a cycle in which the clock signal is “L” and also when the data signal 1 is “1”, an output signal from the output terminal T1 has the signal strength 3.

A signal strength 4 is supplied to the output terminal T1 via switches SW16 and SW12. The switch SW16 turns ON when an inversion of the data signal 1 (DATA 1 with a bar) is “1, ”i.e. when the data signal 1 is “0”, while the switch SW12 turns ON when an inversion of the clock signal (CK with a bar) is “H”, i.e. when the clock signal is “L”. With this arrangement, in the first half of a cycle in which the clock signal is “L” and also when the data signal 1 is “0”, an output signal from the output terminal T1 has the signal strength 4.

In the meantime, the separation section 35 on the side of the receiving LSI 33 is, as FIG. 8 illustrates, provided with a first data detection circuit 36a and a second data detection circuit 36b, respectively, in order to separate the data signal 1 and the data signal 2 from the 4-valued logic signal. The 4-valued logic signal is supplied to these data detection circuits 36a and 36b and a clock detection circuit 37.

In the subsequent stage of the first data detection circuit 36a, a delay circuit 38a and a latch circuit 39a are provided. Similarly, in the subsequent stage of the second data detection circuit 36b, a delay circuit 38b and a latch circuit 39b are provided.

The clock detection circuit 37 outputs “H” when the signal strength is 1 or 2, or outputs “L” when the signal strength is 3 or 4. That is to say, to constitute the clock detection circuit 37 by the voltage comparator 10 described in Embodiment 1 with reference to FIG. 4, a threshold voltage is set to be a voltage value between the signal strengths 2 and 3. With this arrangement, an output signal A from the clock detection circuit 37 is equivalent to the clock signal before the synthesis, as described in FIG. 9(b).

In contrast, the first data detection circuit 36a outputs “0” only when the signal strength is 4, and otherwise outputs “1”. Thus, as illustrated in FIG. 9(b), an output signal Ba from this data detection circuit 36a includes a value corresponding to the data signal 1 before the synthesis to produce the 4-valued signal in the sending LSI 32, only when the clock detection circuit output A is “L”, and hence the output signal Ba is always “1” when the clock detection circuit output A is “H”.

The second data detection circuit 36b outputs “1” only when the signal strength is 1, and otherwise outputs “0”. Thus, as illustrated in FIG. 9(b), an output signal Bb from the data detection circuit 36b includes a value corresponding to the data signal 2 before the synthesis to produce the 4-valued signal in the sending LSI 32, only when the clock detection circuit output A is “H”, and hence the output signal Bb is always “0” when the clock detection circuit output A is “L”.

The respective output signals Ba and Bb from the data detection circuits 36a and 36b are delayed in the respective delay circuits 38a and 38b, and in the respective latch circuits 39a and 39b, the output signals Ba and Bb are latched by means of the output signal A from the clock detection circuit 37.

As in FIG. 9(c), respective output signals from the latch circuits 39a and 39b are logically equivalent to the data signals before the synthesis to produce the 4-valued signal in the sending LSI 32, and the waveforms of the respective output signals are also equivalent to the waveforms of the data signals. The output signals from the latch circuits 39a and 39b are outputted from the separation section 35, along with the restored clock signal (clock detection circuit output A).

In the arrangement of FIG. 8, an inverter is provided in a clock signal input stage of the latch circuit 39b so that the data detection circuit outputs Ba and Bb are latched by means of clock signals in opposite phase to each other. However, it is easy to further add a latch circuit (not illustrated) in the subsequent stage in order to cause the data signals 1 and 2 to be in sync with clock signals which is in identical phase with each other.

Further, to add a data signal to be synthesized, the number of signal strengths that the multivalued logic signal can have are increased.

For instance, provided that 3 data signals are to be synthesized, the following arrangement is adopted: 6 stages of signal strengths are provided, respective signal strengths 1 and 2 correspond to “1” and “0”, of a data signal 1, respective signal strengths 3 and 4 correspond to “1” and “0” of a data signal 2, and respective signal strengths 5 and 6 correspond to “1”, and “0” of a data signal 3. Then in the first half (“L”) of the basic period, any one of the signal strengths 3-6 is outputted, while in the second half (“H”) of the basic period, either of the signal strengths 1 and 2 is outputted.

With this arrangement, it is possible to synthesize a 6-valued logic signal from one clock signal and 3 data signals, and in accordance with the signal strengths, the 6-valued logic signal can be separated into one clock signal and 3 data signals.

When the number of the data signals is odd as in the above-mentioned example, the number of the signal strengths to be outputted in the first half is different from the number of the signal strengths in the second half. In the meantime, when the number of the data signals is even, the number of the signal strengths to be outputted in the first half is identical with the number of the signal strengths in the second half. Thus, to easily realize the circuit, it is preferable that the number of the data signals to be synthesized is even.

[Embodiment 4]

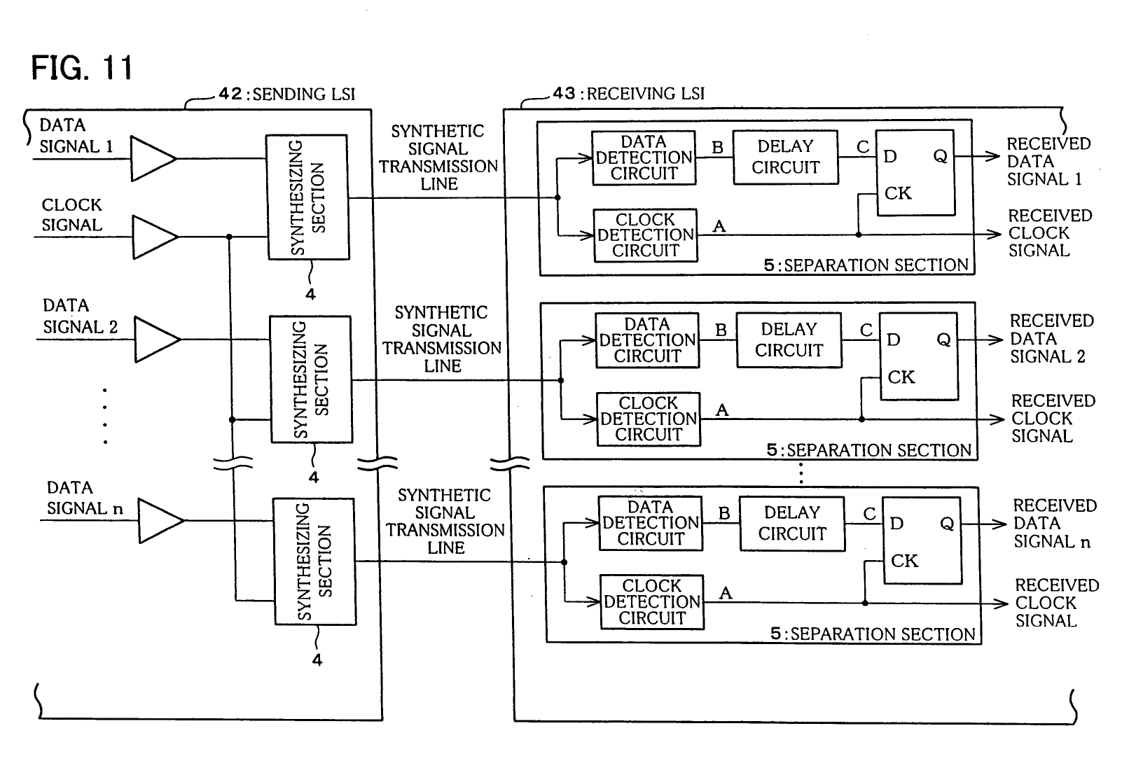

Referring to FIGS. 11-13, yet another embodiment of the present invention will be described below. By the way, members having the same functions as those described in Embodiments 1-3 are given the same numbers, so that the descriptions are omitted for the sake of convenience.

Embodiments 1-3 are arranged in the following manner. In a sending LSI 2, 12, or 32, one or more data signal(s) is synthesized with a clock signal so that one multivalued logic signal is produced, and this multivalued logic signal is transmitted to a receiving LSI 3, 13, or 33 via a single synthetic signal transmission line. Then in the receiving LSI 3, 13, or 33, the multivalued logic signal is separated into the original clock signal and data signal(s).

In this connection, the present embodiment specifically describes a preferable arrangement of a signal transmission system in which more than two data signals are transmitted from a sending LSI to a receiving LSI.

A signal transmission system of FIG. 11 is arranged in such a manner that, when n data signals 1-n are transmitted from a sending LSI 42 to a receiving LSI 43, n synthesizing circuits 4 and n separation circuits 5 are provided and all of these data signals 1-n are synthesized with a common clock signal which is in sync with all of the data signals 1-n, so that multivalued logic signals which have been produced as a result of the synthesis are transmitted.

This arrangement is suitable for a case when the data signals 1-n to be transmitted are homogeneous, for example, when sets of display data, the number of the sets being equivalent to the number of bits, are transmitted from the sending LSI 42 to the receiving LSI 43 in a parallel manner.

That is to say, when homogeneous signals such as sets of display data are transmitted in a parallel manner via a plurality of transmission lines, it is preferable to arrange all circuits regarding these transmission lines in an identical manner, in order to eliminate the variation between the transmission lines caused by the difference between the circuit arrangements.

It has already been pointed out that the variation between the transmission lines is unavoidable, and this holds true with the circuit arrangement of the transmission lines. That is, no matter how precisely the circuit arrangement is done, the variation caused in the manufacturing process is unavoidable. For this reason, when homogeneous signals such as sets of display data are transmitted in a parallel manner via a plurality of transmission lines, the adverse effect of the variation gets more acute, if only one of the data signals is synthesized with the clock signal and a multivalued logic signal as a result of the synthesis is transmitted, while the remaining data signals are transmitted without being synthesized.

In this connection, in the arrangement of FIG. 11, each of the transmission paths identically includes the variation caused in the manufacturing process and hence it is possible to significantly reduce the adverse effect of the variation.

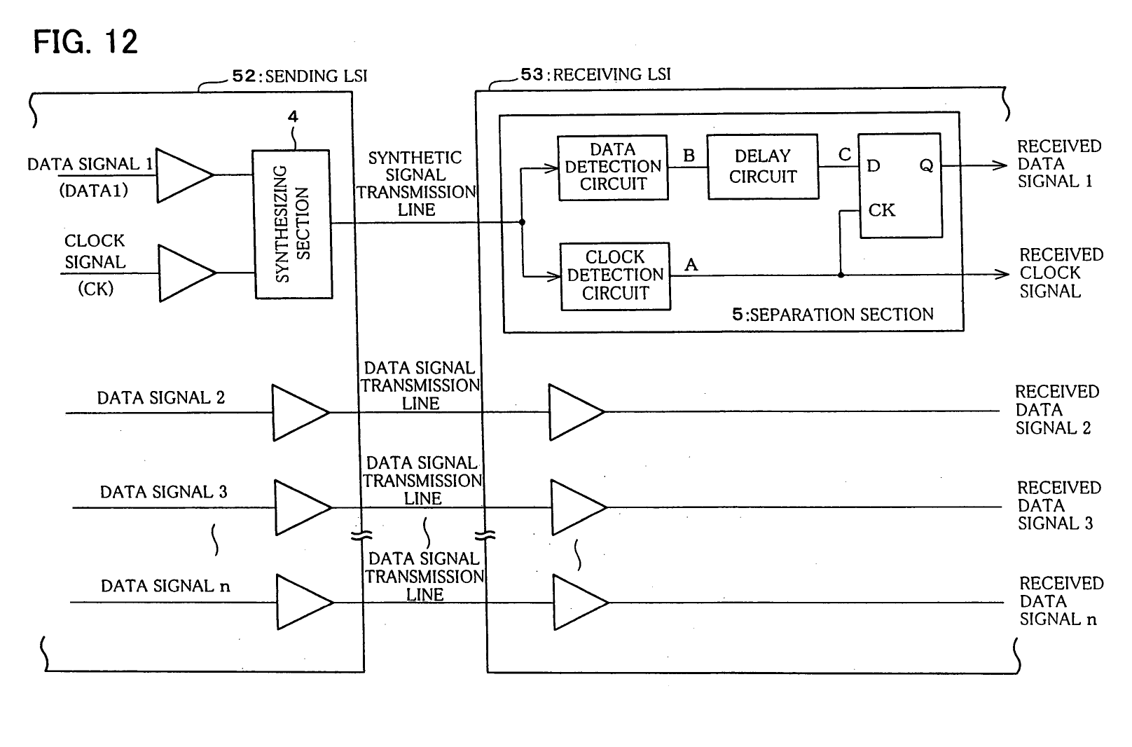

In the meantime, in a signal transmission system of FIG. 12, when n data signals 1-n are transmitted from a sending LSI 52 to a receiving LSI 53, a multivalued logic signal is produced by synthesizing some of the data signals with the clock signal, which pass through transmission lines with which respective synthesizing circuits 4 and separation circuits 5 are provided, while the remaining data signals 2-n are transmitted without being synthesized. In the present embodiment, only a data signal 1 is synthesized with the clock signal so that the multivalued logic signal is produced.

This arrangement is suitable for a case when some of a plurality of data signals 1-n to be transmitted are faster than the remaining ones.

That is to say, a fast data signal is in sync with a clock signal with a high frequency so that the above-mentioned problem of a setup/hold period comes up, while a slow data signal is in sync with a clock signal with a low frequency so that the above-mentioned problem of a setup/hold period is not serious.

Thus, when a plurality of signals each having different speed are transmitted, the arrangement of the present invention is preferably adopted only for those fast data signals which cause the above-mentioned problem of a setup/hold period, while the remaining slow data signals are transmitted without modification, and a clock signal separated in the separation section 5 is used after frequency dividing.

This arrangement allows the entire circuit to be smaller than the circuit in the case of synthesizing all data signals with a clock signal in sync with the data signals and then performing transmission.

Further, the arrangement of FIG. 12 is suitable for a case when a plurality of data signals 1-n are transmitted through respective transmission lines having different lengths.

In a case of a data signal passing through a long transmission line, arranging a sufficient setup period is more difficult than a case of a data signal passing through a short transmission line, even if the clock signals with which the respective signals are synchronized have a uniform frequency, since the above-mentioned timing variation is large.

Thus, when a plurality of data signals are transmitted through respective transmission lines having different lengths, the arrangement of the present invention is adopted only for those data signals passing through long transmission paths, which cause the above-mentioned problem of a setup/hold period, while the remaining data signals passing through short transmission paths are transmitted without modification.

This arrangement also allows the entire circuit to be smaller than the circuit in the case of synthesizing all data signals with a clock signal in sync with the data signals and then performing transmission.

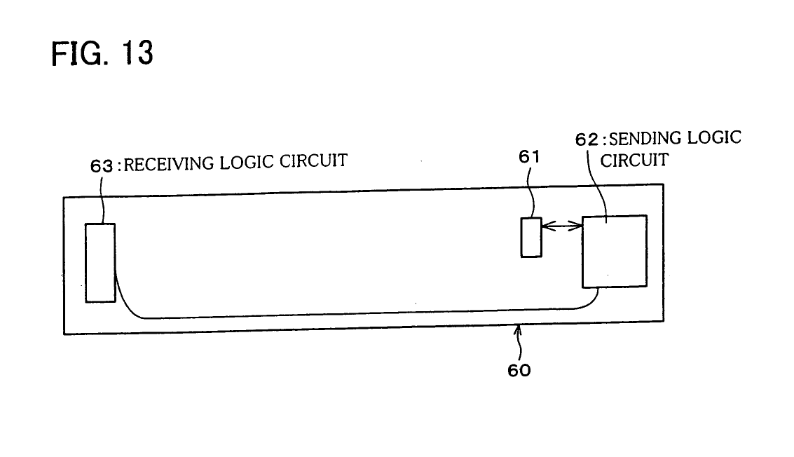

The above-described signal transmission system of FIG. 12 is arranged such that the sending logic circuit and the receiving logic circuit are mounted on respective LSIs 52 and 53. However, as illustrated in FIG. 13, the present arrangement is also suitable for such an arrangement that a sending logic circuit 62 and a receiving logic circuit 63 are mounted on a single LSI 60 so that transmission lines have significantly different lengths.

LSIs constituting such as a liquid crystal driver of a liquid crystal display device have recently been slim-shaped as in FIG. 13, because of the increase of aspect ratios of the LSIs in response to requirements such as narrowing the frame. In an LSI 60 with such a shape, a transmission path from a sending logic circuit 62 provided around one end of the LSI 60 in the longitudinal direction to a receiving logic circuit 63 provided around the other end is several times to several dozen times longer than a transmission line between a receiving logic circuit 61 provided around the sending logic circuit 62 and the sending logic circuit 62. As a result, even if these transmission paths include identical variation caused by the manufacturing process, the timing difference between the clock signal and the data signal is multiplied several times to several dozen times.

On this account, when a clock signal and a data signal in sync with the clock signal are transmitted between logic circuits mounted on an LSI with a high aspect ratio, it is suitable to adopt the arrangement of FIG. 12, when problems are caused by the timing difference between the clock signal and the data signal due to the difference of the lengths of the transmission lines.

Note that, a specific arrangement of the LSI 60 in FIG. 13 is such that, for instance, the sending logic circuit 62 is control section, and members provided around the sending logic circuit 62 are the receiving logic circuit 61, which causes no problem of timing difference between the clock signal and the data signal, as a cache memory, and the receiving logic circuit 63, which causes the problem of timing difference between the clock signal and the data signal, as a shift register for an interface.

Although the arrangements of FIGS. 11 and 12 adopt the synthesizing section 4 and the separation section 5 both used in the signal transmission system of Embodiment 1, it is possible to adopt such an arrangement that the synthesizing section 14 and the separation section 15 for a current signal used in Embodiment 2 are used instead of the foregoing sections, and the current mirror circuit 20 is added to the receiving LSI 43 or 53. Similarly, it is possible to adopt the synthesizing section 34 and the separation section 35 used in the signal transmission system of Embodiment 3.

[Embodiment 5]

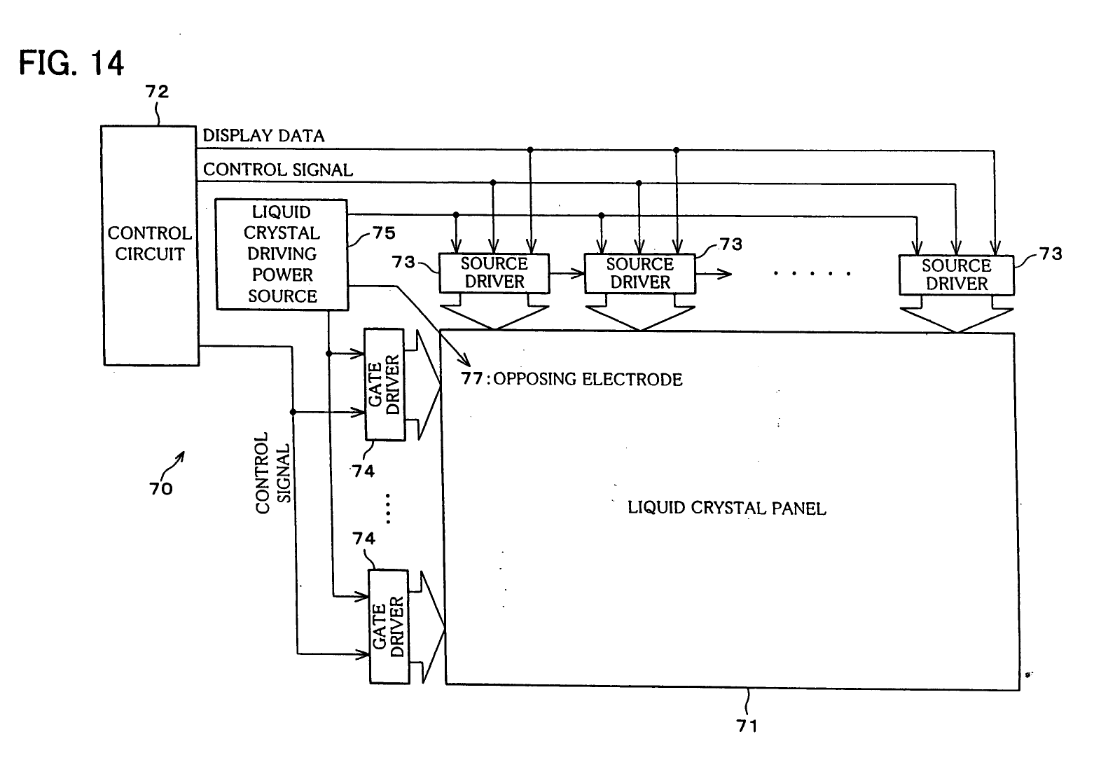

Referring to FIGS. 14-19, still another embodiment of the present invention will be described below. By the way, members having the same functions as those described in Embodiments 1-4 are given the same numbers, so that the descriptions are omitted for the sake of convenience.

The present embodiment describes an arrangement in which a signal transmission system of the present invention is adopted to a liquid crystal drive device of a liquid crystal display device. More specifically, the arrangement of the signal transmission system which has been described in Embodiment 1, in which arrangement a voltage signal is used as a multivalued logic signal and a 3-valued logic signal is produced as a result of the synthesis of a single binary data signal and a single clock signal, is adopted, and between a control circuit and a source driver circuit of a liquid crystal drive device, sets of display data as data signals being synchronized with a clock signal is transmitted.

First, with reference to FIGS. 14-16, a liquid crystal display device adopting a signal transmission system of the present invention will be described. FIG. 14 illustrates a typical arrangement of an active matrix TFT liquid crystal display device which is a kind of the liquid crystal display device.

The liquid crystal display device includes a TFT liquid crystal panel 71 and a liquid crystal drive device 70 for driving the TFT liquid crystal panel 71. The liquid crystal drive device 70 includes a plurality of source driver circuits 73, a plurality of gate driver circuits 74, a control circuit 72, and a liquid crystal driving power source 75.

The control circuit 72 outputs digitalized display data (e.g. R, G, and B signals corresponding to red, green, and blue) and various control signals to the source driver circuits 73, and also outputs various control signals to the gate driver circuits 74. The control signals to the source driver circuits 73 includes a latch strobe signal which is a horizontal synchronizing signal and described later, a start pulse signal, and a clock signal for the source driver. The control signals to the gate driver circuits 74 includes a vertical synchronizing signal and a clock signal for the gate driver. Note that, from the figure, power supply lines for driving the source driver circuits 73 and the gate driver circuits 74 are omitted.

The liquid crystal driving power source 75 supplies a reference voltage for display to the source driver circuits 73 and the gate driver circuits 74, and also supplies a common voltage for display to opposing electrodes of the liquid crystal panel 71.

In this liquid crystal display device, digital display data supplied from the outside is subjected to processes such as timing control in the control circuit 72, and then as display data, transmitted to the source driver circuits 73.

In each of the source driver circuits 73, the supplied display data is latched in a time-division manner, in accordance with the clock signal for the source drivers. Then the display data is latched by means of a latch strobe signal supplied from the control circuit 72, and being in sync with this latch strobe signal, D/A (digital/analog) conversion is performed. Subsequently, the source driver circuit 73 supplies an analog voltage for gray-scale display (i.e. a voltage for gray-scale display), obtained by the D/A conversion, from a liquid crystal drive voltage output terminal to source signal lines 80 which are described later.

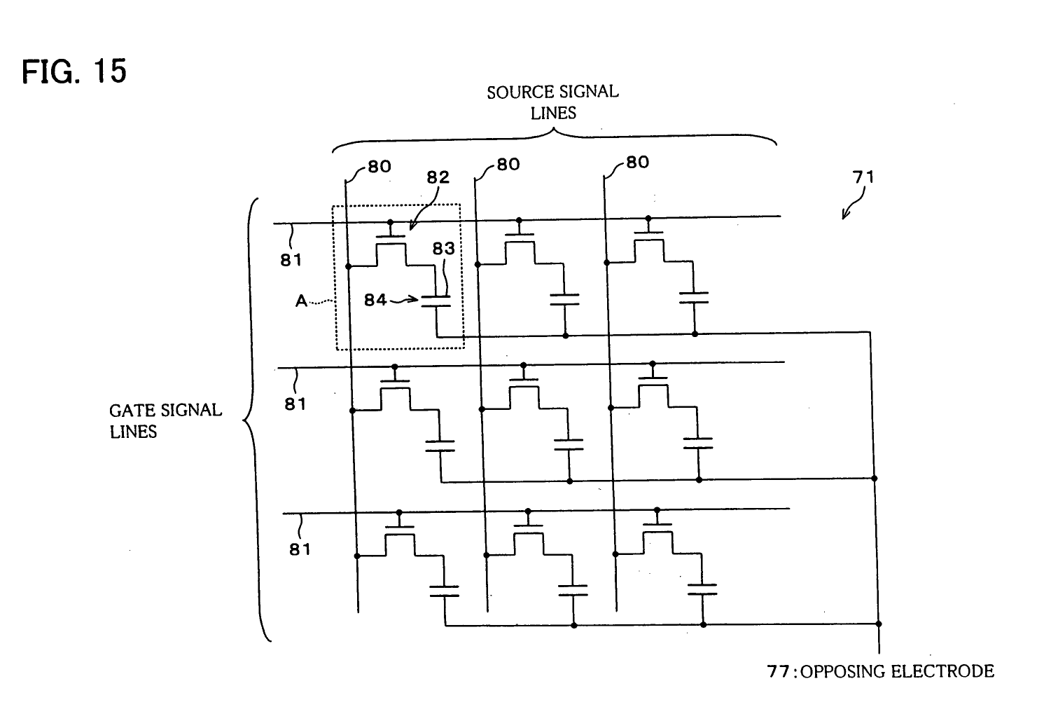

FIG. 15 illustrates an arrangement of the liquid crystal panel 71. The liquid crystal panel 71 is provided with a plurality of source signal lines 80 driven by the foregoing source driver circuits 73 and a plurality of gate signal lines 81 driven by the foregoing gate driver circuits 74, the source signal lines 80 intersecting with the gate signal lines 81. At each of the intersections of the source signal lines 80 and the gate signal lines 81, a pixel electrode 83 and a TFT 82 for controlling the application of a display voltage to the pixel electrode 83 are provided. Between the pixel electrode 83 and an opposing electrode 77, a liquid crystal layer 84 is provided so that a pixel capacitor is formed. In the figure, an area indicated by A corresponds to one pixel.

The source signal lines 80 receive gray-scale display voltages corresponding to luminance of respective pixels for display, from the source driver circuits 73. The gate signal lines 81 receives scanning signals in order to serially turn ON the longitudinally-aligned TFTs 82, from the gate driver circuits 74. Through the TFTs 82 having been turned ON, the voltages of the respective source signal lines 80 are supplied to the pixel electrodes 83 connected to the drains of the respective TFTs 82, so that optical transmittance of each of the liquid crystal layers 84 between the respective pixel electrodes 83 and opposing electrodes 77 changes, and as a result, displaying is carried out.

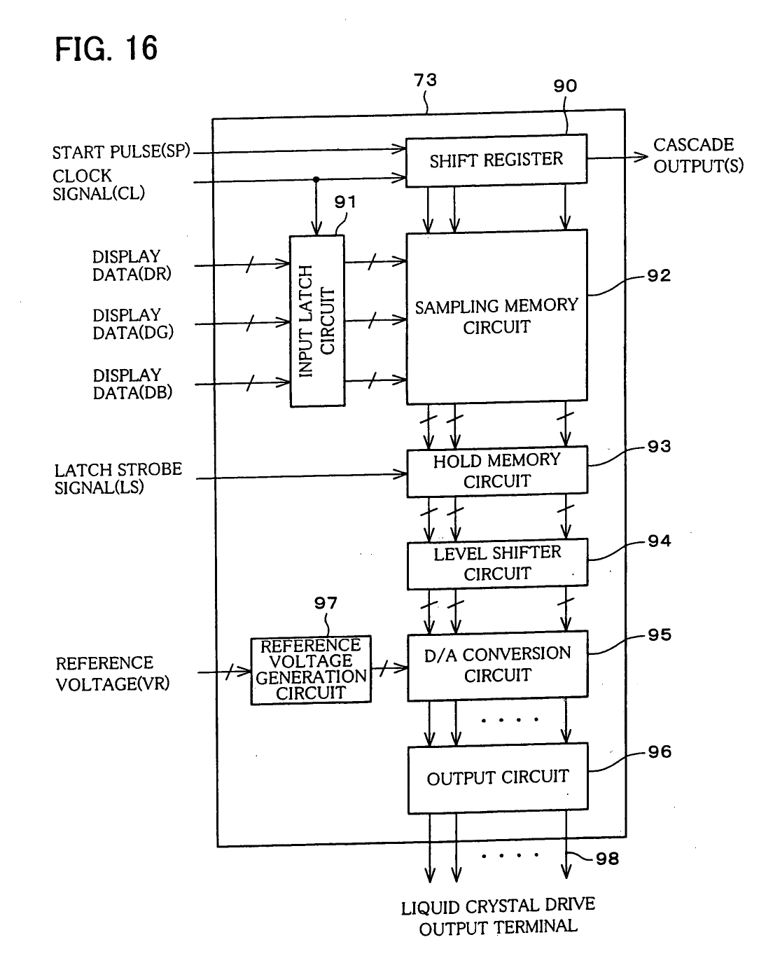

FIG. 16 illustrates a block diagram of the source driver circuit 73. To the source driver circuit 73, a start pulse (SP), a clock signal (CK), a latch strobe signal (LS), sets of digital display data for red, green, and blue (DR, DG, and DB), and a reference voltage (VR) are supplied as described above.

The sets of digital display data for red, green, and blue (each of the sets is, for instance, 8 bits), which are transferred from the control circuit 72, are latched in the input latch circuit 91. On the other hand, the start pulse signal for controlling the transfer of the sets of digital display data for red, green, and blue is synchronized with the clock signal, transferred in a shift register circuit 90, and then from the last stage of the shift register circuit 90 to the source driver circuit 73 which is the subsequent stage, outputted as a start pulse signal SP (cascade output signal S).

Being in sync with output signals from respective stages of the shift register circuit 90, the sets of digital display data for red, green, and blue, having been latched in the input latch circuit. 91, are temporarily stored in a sampling memory circuit 92 in a time-division manner, thereby being outputted to a hold memory circuit 93.

Once the sets of digital display data for red, green, and blue, corresponding to the pixels constituting horizontal lines of the screen, are stored in the sampling memory circuit 92, the hold memory circuit 93 acquires an output signal from the sampling memory circuit 92, in accordance with the latch strobe signal (horizontal synchronization signal). Then the hold memory circuit 93 outputs the acquired signal to a subsequent level shifter circuit 94, while keeping the display data until the next latch strobe signal is supplied.

The level shifter circuit 94 converts a signal level by way of, for instance, boosting, in order to cause the signal level to correspond to a D/A conversion circuit 95 which is in the subsequent stage and provided for processing a voltage level applied to the liquid crystal panel 71. A reference voltage generation circuit 97 generates various analog voltages for gray-scale display, in accordance with the reference voltage VR supplied from the above-mentioned liquid crystal driving power source 75, thereby outputting the generated voltages to the D/A conversion circuit 95.

The D/A conversion circuit 95 selects a single analog voltage from each of the various analog voltages supplied from the reference voltage generation circuit 97, in accordance with the sets of digital display data for red, green, and blue, which have been subjected to the level conversion in the level shifter circuit 94. The analog voltage representing the gray-scale display is supplied from each of liquid crystal drive voltage output terminals 98 to the corresponding source signal line 80 of the liquid crystal panel 71 via an output circuit 96.

The output circuit 96 is basically a buffer circuit for low-impedance conversion, including, for instance, a voltage follower circuit using a differential amplifier circuit.

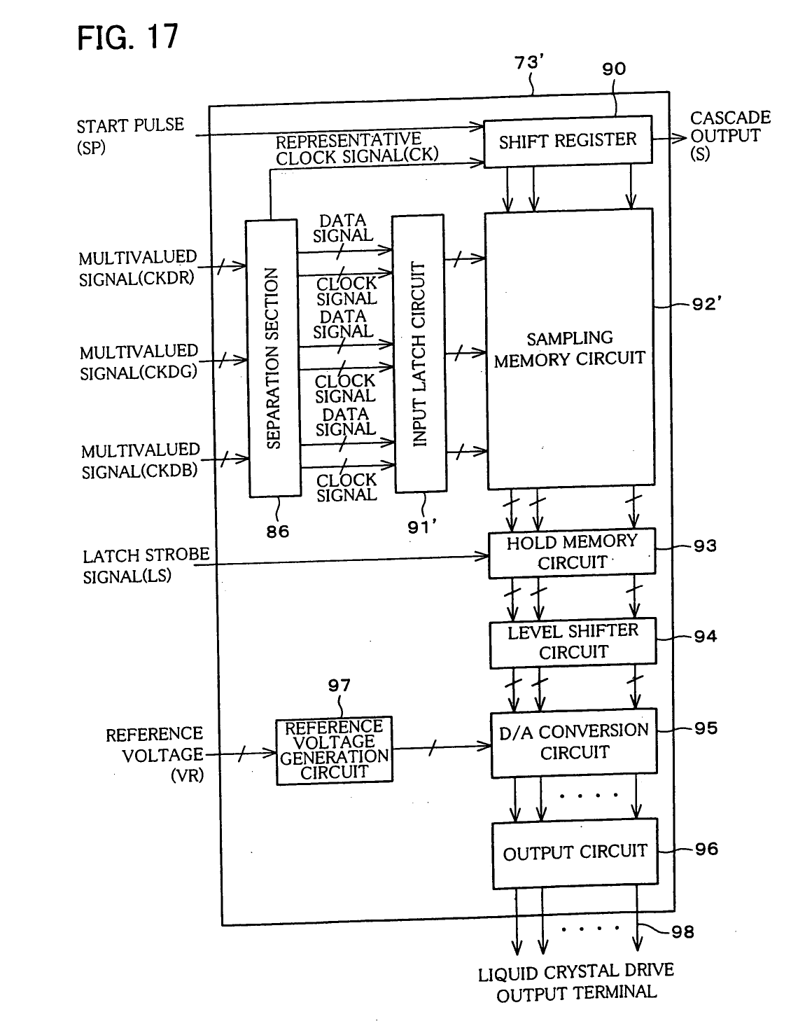

FIG. 17 is a block diagram, illustrating a source driver circuit regarding such an arrangement that, sets of digital display data for red, green, and blue (DR, DG, and DB) are synthesized with a clock signal (CK) so that multivalued logic signals are produced, and these multivalued logic signals are transmitted from the control circuit 72 to the source driver circuit 73 of the liquid crystal drive device 70 illustrated in FIG. 14. Note that, the source drive circuit of the present invention, is numbered 73′, and the control circuit of the present invention is numbered 72′.

The source driver circuit 73′ in FIG. 17 is arranged in the following manner. In a control circuit (not illustrated), sets of digital display data for red, green, and blue (DR, DG, and DB) are synthesized with a clock signal (CK) so that multivalued logic signals are produced. Then these multivalued logic signals, i.e. red, green, and blue multivalued signals (CKDR, CKDG, and CKDB) are supplied to the source driver circuit 73′. The source driver circuit 73′ is provided with a separation section 86, and this separation section 86 separates the red, green, and blue multivalued signals (CKDR, CKDG, and CKDB) into the original sets of digital display data for red, green, and blue (DR, DG, and DB) and the original clock signal (CK).

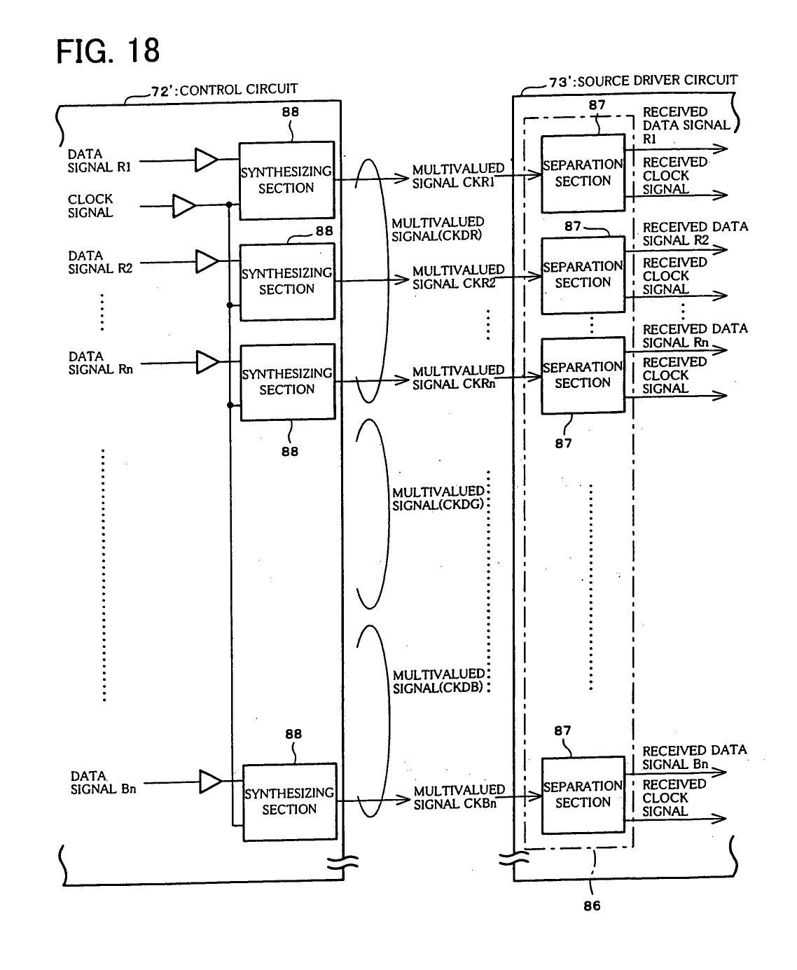

FIG. 18 illustrates (i) a substantial part of the control circuit 72′ which synthesizes the sets of digital display data for red, green, and blue (DR, DG, and DB) with the clock signal (CK) so as to produce the multivalued logic signals (CKDR, CKDG, and CKDB) and thereby transmitting the same, and (ii) a substantial part of the source driver 73′.

In FIG. 18, data signals R1-Rn correspond to the set of digital display data for red (DR), data signals G1-Gn correspond to the set of digital display data for green (DG), and data signals B1-Bn correspond to the set of digital display data for blue (DB). If each of the sets of digital display data for red, green, and blue (DR, DG, and DB) is an 8-bit digital signal, n=8.

On the side of the control circuit 72′, synthesizing section 88 are provided on respective signal lines for the corresponding sets of digital display data for red, green, and blue (DR, DG, and DB). On this account, when each of the sets of digital display data for red, green, and blue (DR, DG, and DB) is an 8-bit digital signal, the number of the synthesizing section 88 is 8×3=24.

Since the data signals R1-Rn, G1-Gn, and B1-Bn are all binary data signals, the synthesizing section 88 is arranged so as to be identical with the synthesizing section 4 described in Embodiment 1. As a matter of course, when the multivalued logic signals are current signals, the synthesizing section 88 is arranged so as to be identical with the synthesizing section 14 described in Embodiment 2.

Further, on the side of the source driver circuit 73′, a separation section 87 are provided. The number of the separation section 87 corresponds to the number of the synthesizing section 88 provided on the side of the control circuit 72′. On this account, when each of the sets of digital display data for red, green, and blue (DR, DG, and DB) is an 8-bit digital signal, the number of the separation section 87 is 8×3=24.

Since the data signals R1-Rn, G1-Gn, and B1-Bn are all binary signals and synthesized to produce 3-valued logic signals, the separation section 87 is arranged so as to be identical with the separation section 5 described in Embodiment 1. As a matter of course, when the multivalued logic signals are current signals, the separation section 87 is arranged so as to be identical with the separation section 15 described in Embodiment 2.

The data signals R1-Rn, G1-Gn, and B1-Bn which have been separated are supplied from the separation section 87 to respective input latch circuits 91′, being paired with respective clock signals which have been separated. Then one of the clock signals outputted from the corresponding separation section 87 is supplied to the shift register 90, as a representative clock signal.

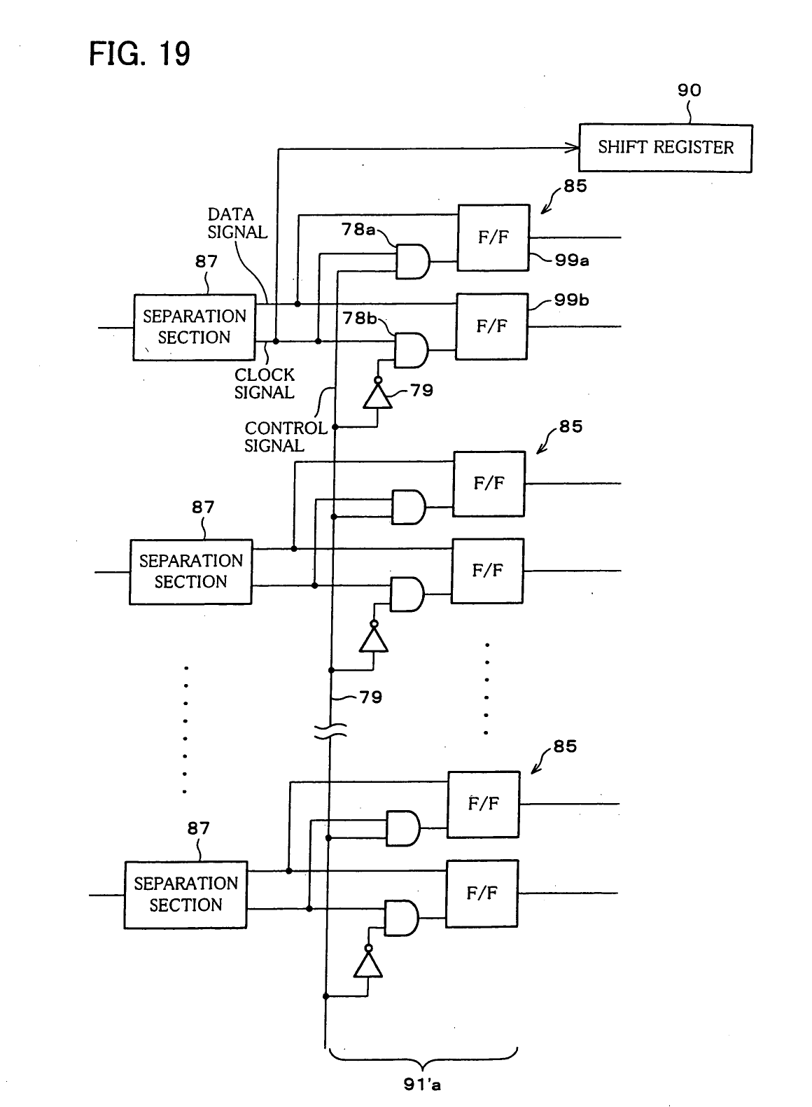

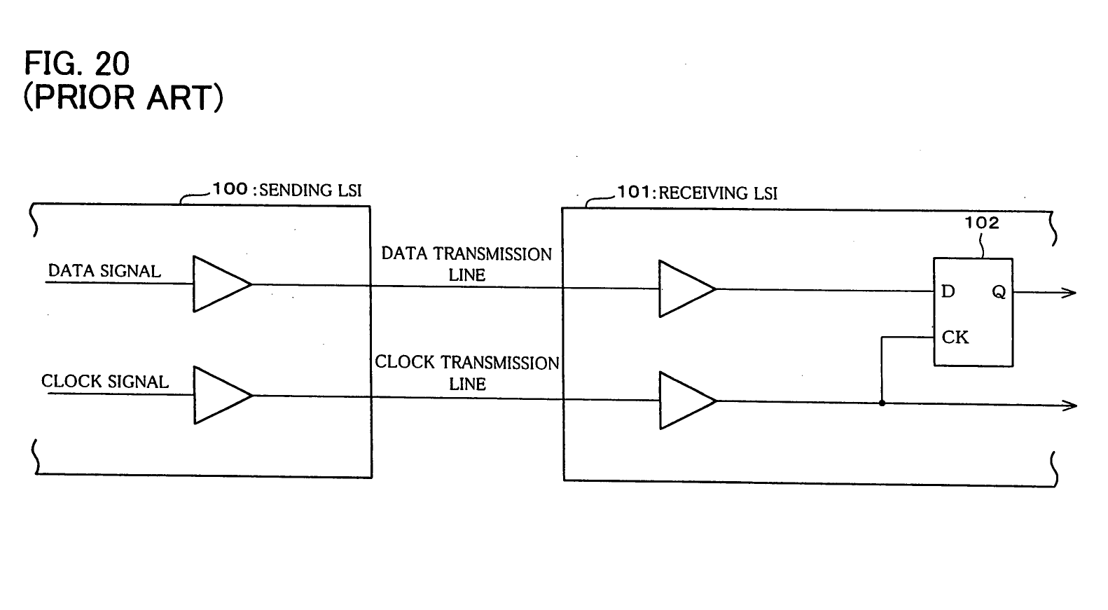

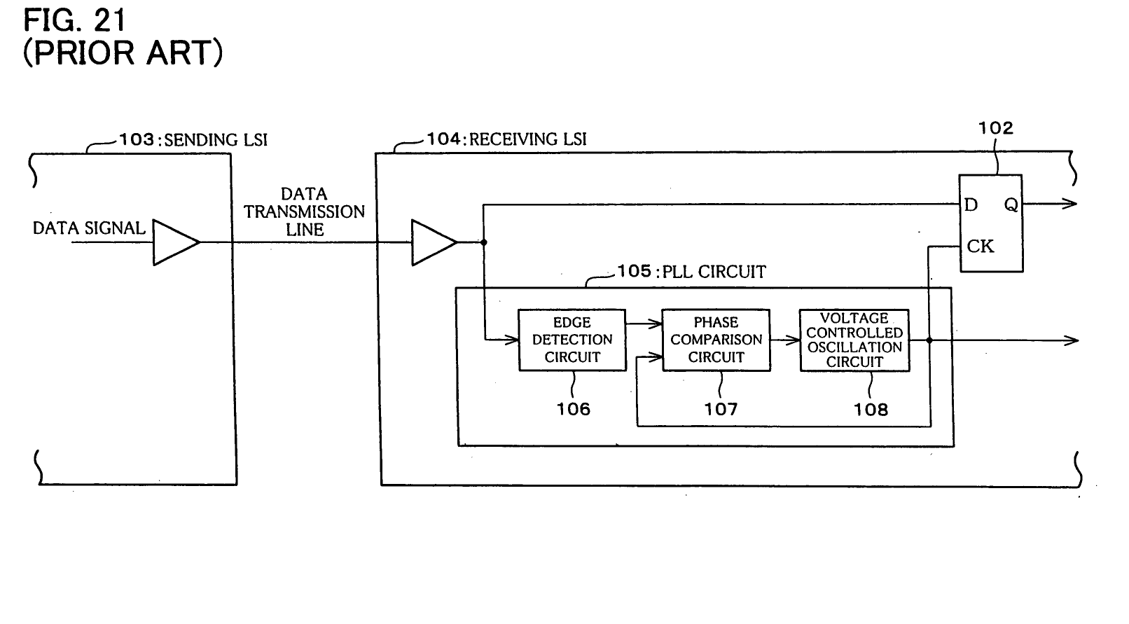

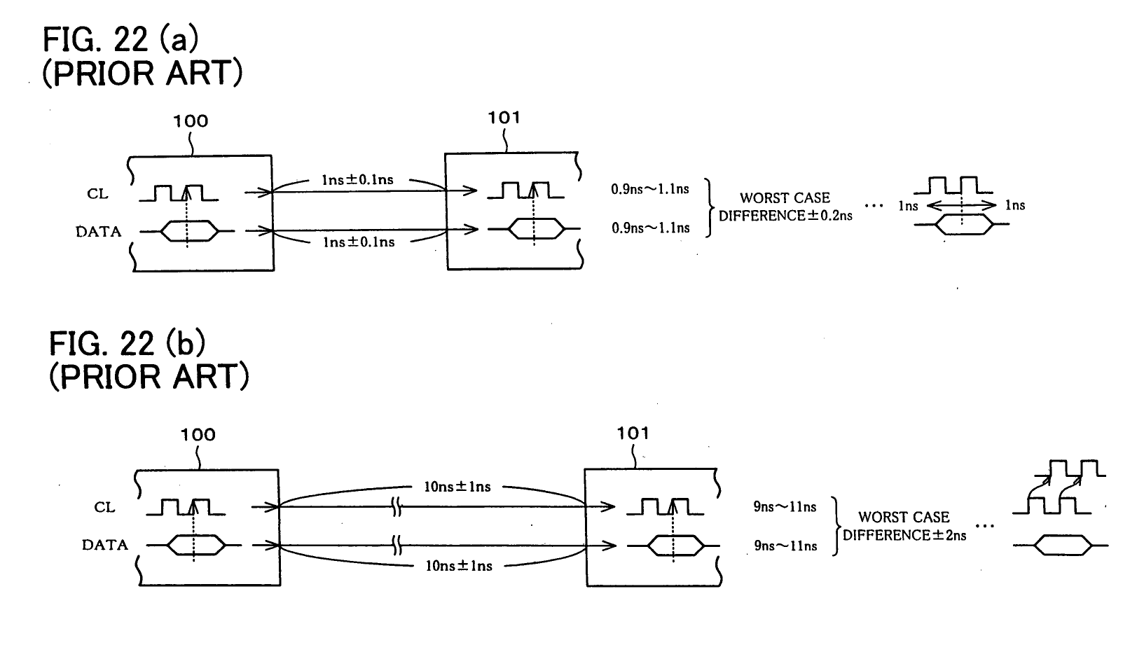

FIG. 19 illustrates an arrangement of the input latch circuits 91′ to which the data signals R1-Rn, G1-Gn, and B1-Bn which have been separated are supplied, being paired with respective clock signals which have been separated.

The input latch circuits 91′ include respective latch circuit sections 85 provided for the respective separation section 87. Each of the latch circuit sections 85 includes latch circuits 99a and 99b. To respective data input terminals of the latch circuits 99a and 99b, the data signals are supplied from the separation section 87. In the meantime, to a clock terminal of the latch circuit 99a, the clock signal from the separation section 87, being ANDed in an AND circuit 78a with a control signal passing through a signal line 79, is supplied. To a clock terminal of the latch circuit 99b, the clock signal from the separation section 87, being ANDed in an AND circuit 78b with an inversion of the control signal passing through the signal line 79, is supplied.

With this arrangement, the flip-flop circuits 99a and 99b alternately operate so that the data signals are latched by means of the clock signals. As a result, the number of signal lines for the data signals is doubled, and hence, for instance, 24 data signals are converted to 48 signals.

Since the number of the signal lines is doubled, an operating frequency of the shift register circuit 90 is halved so that an operation margin is doubled. On this account, even if a clock signal among the clock signals having been separated in the separation section 87 is supplied to the shift register circuit 90, no problems are caused to the operation.

Note that, using an arbitration circuit, among the plurality of clock signals supplied from the plurality of separation section 87, a clock signal with the most appropriate timing may be selected as a representative clock signal, and then supplied to the shift register circuit 90.

As described above, in the present embodiment, the signal transmission system of the present invention is adopted to the control circuit and source driver circuit of the liquid crystal drive device of the liquid crystal display device, and the data signals to be synthesized with the clock signal in order to producing the multivalued logic signals are the sets of digital display data for red, blue and green, rather than signals such as a start pulse signal.

The sets of digital display data for red, green, and blue are signals varying more quickly than a start pulse signal and a latch strobe signal so that the constraint of the setup/hold period is severe and hence it is difficult to obtain a sufficient design margin of the timing when the speedup of the clock signal further proceeds or the transmission lines are further elongated. Thus, synthesizing the sets of digital display data for red, green, and blue with a clock signal is more effective than synthesizing a clock signal with a start pulse signal or a latch strobe signal.

Further, in course of synthesizing the sets of digital display data for red, green, and blue with a clock signal, since all signal lines of the respective sets of digital display data for red, green, and blue (DR, DG, and DB) are each uniformly provided with the synthesizing section 88 and separation section 87, the variations between the signal lines due to the differences of the arrangement are eliminated.

As described above, the signal transmission method of the present invention is characterized in that, when a logic data signal in sync with a clock signal is transmitted from a logic circuit to another logic circuit, in a sending end, a multivalued logic signal is synthesized from the clock signal and the logic data signal and outputted, and in a receiving end, the multivalued logic signal is separated into the clock signal and the logic data signal.

Thus, it is possible to eliminate the timing difference between the clock signal and the logic data signal, which is caused due to such a reason that the clock signal and the logic data signal are transmitted through different transmission paths.

According to this arrangement, it is possible to eliminate the constraint of a setup/hold period in a receiving end without including complicated synchronizing circuits such as a PLL circuit in a logic circuit of the receiving end, and this makes it possible to accommodate to further speedup of a clock signal in future and elongation of a transmission path.

As described above, the first logic circuit of the present invention is arranged so as to comprise first synthesizing means for synthesizing one clock signal with one logic data signal in sync with the clock signal so as to produce one multivalued logic signal.

According to this arrangement, since the first synthesizing means synthesizes one clock signal with one logic data signal so as to produce one multivalued logic signal, it is possible to eliminate the timing difference between the clock signal and the logic data signal transmitted using the logic circuit, which is caused due to such a reason that the clock signal and the logic data signal are transmitted through different transmission paths.

On this account, as already described in relation to the signal transmission method, the logic circuit is adopted as a sending logic circuit for sending a clock signal and a logic data signal and combined with a logic circuit (described later) suitable for a receiving end of the present invention, and this arrangement makes it possible to accommodate to further speedup of a clock signal in future and elongation of a transmission path.

As described above, the second logic circuit of the present invention is arranged so as to comprise second synthesizing means for synthesizing one clock signal with a plurality of logic data signals in sync with the clock signal so as to produce one multivalued logic signal.

According to this arrangement, since the second synthesizing means synthesizes one clock signal with a plurality of logic data signals so as to produce one multivalued logic signal, it is possible to eliminate the timing difference between the clock signal and the logic data signals transmitted using the logic circuit, which is caused due to such a reason that the clock signal and the logic data signals are transmitted through different transmission paths. Further, since one clock signal is synthesized with a plurality of logic data signals, the efficiency of transmitting the clock signal in this arrangement is better than the efficiency in the case of synthesizing one logic data signal with a clock signal.

On this account, as already described in relation to the signal transmission method, the logic circuit is adopted as a sending logic circuit for sending a clock signal and a logic data signal and combined with a logic circuit (described later) suitable for a receiving end of the present invention, and this arrangement makes it possible to accommodate to further speedup of a clock signal in future and elongation of a transmission path.

Further, the first and second logic circuit of the present invention, which are the sending logic circuits, are characterized in that logic data signals to be transmitted include a fast logic data signal and a slow logic data signal, and the first or second synthesizing means synthesizes the fast logic data signal with the clock signal.

The fast data signal is in sync with a clock signal with a high frequency so that the above-mentioned problem of a setup/hold period comes up, while the slow data signal is in sync with a clock signal with a low frequency so that the above-mentioned problem of a setup/hold period is not serious.

Thus, when a plurality of signals each having different speed are transmitted, the arrangement of the present invention is adopted only for the fast logic data signal which causes the above-mentioned problem of a setup/hold period, while the remaining slow logic data signal is transmitted without modification, and a clock signal having been separated is used after frequency dividing.

This arrangement allows the entire circuit to be smaller than the circuit in the case of synthesizing a clock signal with all logic data signals in sync with the clock signal and then performing transmission.

Further, the first and second logic circuits of the present invention, adopted as the sending logic circuits, are characterized in that, the logic data signals to be transmitted include a logic data signal transmitted via a long transmission path and a logic data signal transmitted via a short transmission path, and the first or second synthesizing means synthesizes the logic data signal transmitted via the long transmission path with the clock signal.

As in the foregoing case of the signal speed, a logic data signal transmitted via a long transmission path causes a high degree of timing difference, even if a common clock signal with which logic data signals synthesize has a consistent frequency. On this account, the problem of a setup/hold period is more serious in this case, compared with the case of a logic data signal transmitted via a short transmission path.

Thus, when a plurality of signals are transmitted through different transmission paths, the arrangement of the present invention is adopted only for the logic data signal passing through a long transmission line, which causes the above-mentioned problem of a setup/hold period, while the remaining logic data signal passing through a short transmission paths is transmitted without modification.

This arrangement allows the entire circuit to be smaller than the circuit in the case of synthesizing a clock signal with all logic data signals in sync with the clock signal and then performing transmission.

Further, the first and second logic circuits of the present invention, adopted as the sending logic circuits, are characterized in that, one or more logic data signals include a plurality of homogeneous logic data signals, and the first or second synthesizing means are provided so as to correspond to the logic data signal or homogeneous logic data signals, which is/are to be synthesized, in order to cause respective circuit arrangements regarding the logic data signal(s) to be uniform.

For instance, when the logic data signals to be synthesized are a plurality of homogeneous signals such as sets of display data corresponding to the number of bits, causing all of the circuit arrangements provided on respective transmission lines to be uniform allows all of the transmission lines to have uniform variation caused by the manufacturing process, so that the adverse effects of the variation due to the difference of the circuit arrangements can be restrained.

Further, the first and second logic circuits of the present invention, adopted as the sending logic circuits, are characterized in that, the first or second synthesizing means includes: a plurality of signal strength sources having different signal strengths; and a plurality of switches provided between said plurality of signal strength sources and an output section which outputs said one multivalued logic signal, and the plurality of switches are controlled by one or more logic data signals and one clock signal, which are to be synthesized.

This arrangement, which is an embodiment of the first or second synthesizing means, makes it possible to easily obtain the first or second synthesizing means and easily realize the logic circuit of the present invention, which is the sending logic circuit.

Further, the first and second logic circuits of the present invention, adopted as the sending logic circuits, are characterized in that, the first or second synthesizing means performs the synthesis so as to produce a multivalued logic signal as a voltage signal.

When the multivalued logic signal is a voltage signal, the logic circuit can be easily realized by adopting a CMOS logic circuit, and this makes it possible to design the circuit.

Further, the first and second logic circuits of the present invention, adopted as the sending logic circuits, are characterized in that, the first or second synthesizing means performs the synthesis so as to produce a multivalued logic signal as a current signal.

When the multivalued logic signal is a current signal, the logic circuit is easily constructed using a constant current operation of a CMOS device. This makes it possible to realize signal transmission with little voltage oscillation, and hence unnecessary radiation can be reduced.

As described above, the third logic circuit of the present invention is arranged so as to comprise first separation means for separating a multivalued logic signal, which is produced by synthesizing one clock signal with one logic data signal in sync with said one clock signal, into said one clock signal and one logic data signal.

According to this arrangement, since one multivalued logic signal, having been produced by synthesizing one clock signal with one logic data signal in sync with the clock signal, is separated into the original clock signal and logic data signal by the first separation means, it is possible to eliminate the timing difference between the clock signal and the logic data signal received by the logic circuit, which is caused due to such a reason that the clock signal and the logic data signal are transmitted through different transmission paths.

On this account, as already described in relation to the signal transmission method, the logic circuit is adopted as a receiving logic circuit for receiving a clock signal and a logic data signal and combined with the above-mentioned logic circuit suitable for a sending end of the present invention, and this arrangement makes it possible to accommodate to further speedup of a clock signal in future and elongation of a transmission path.

As described above, the fourth logic circuit of the present invention is arranged so as to comprise second separation means for separating a multivalued logic signal, which is produced by synthesizing one clock signal with a plurality of logic data signals in sync with said one clock signal, into said one clock signal and said logic data signals.

According to this arrangement, since one multivalued logic signal, having been produced by synthesizing one clock signal with a plurality of logic data signals in sync with the clock signal, is separated into the original clock signal and the plurality of logic data signals by the second separation means, it is possible to eliminate the timing difference between the clock signal and the plurality of logic data signals received by the logic circuit, which is caused due to such a reason that the clock signal and the plurality of logic data signals are transmitted through different transmission paths.

On this account, as already described in relation to the signal transmission method, the logic circuit is adopted as a receiving logic circuit for receiving a clock signal and a logic data signal and combined with the above-mentioned logic circuit suitable for a sending end of the present invention, and this arrangement makes it possible to accommodate to further speedup of a clock signal in future and elongation of a transmission path.

The third and fourth logic circuits, adopted as the receiving logic circuits, are characterized in that, in accordance with signal strength, the first or second separation means separates a clock signal from a multivalued logic signal, restore a logical value(s) of one or more logic data signal(s), and restore waveforms of the logic data signal(s) from the logical value(s), using the clock signal having been separated.

In this manner, in accordance with signal strength, a clock signal is separated from a multivalued logic signal, a logic value(s) of one or more logic data signal(s) is restored, and consequently an waveform of the logic data signal(s) is restored, so that the multivalued logic signal can be easily separated into the original clock signal and the original logic data signal(s) in sync with the clock signal.

With this arrangement, it is possible to easily obtain the first and second separation means and easily realize the logic circuit of the present invention, which is the receiving logic circuit.

Further, the third and fourth logic circuits, adopted as the receiving logic circuits, are characterized in that, the multivalued logic signal separated by the first or second separation means is a voltage signal.

As described above, when the multivalued logic signal is a voltage signal, the logic circuit is easily realized as a CMOS logic circuit so that arranging the logic circuit becomes easier.

Further, the third and fourth logic circuits, adopted as the receiving logic circuits, are characterized in that, the multivalued logic signal separated by the first or second separation means is a current signal.

As described above, when the multivalued logic signal is a current signal, the logic circuit is easily constructed using a constant current operation of a CMOS device. This makes it possible to realize signal transmission with little voltage oscillation, and hence unnecessary radiation can be reduced.

Further, the third logic circuit of the present invention, adopted as the receiving logic circuit, is characterized in that, the first separation means includes: a clock restoration circuit which restores the clock signal from the multivalued logic signal, in accordance with signal strength; a logical value restoration circuit which restores, in accordance with signal strength, a logical value of one logic data signal from the multivalued logic signal so as to generate a logical value restoration data signal; and a latch circuit which latches the logical value restoration data signal by means of the clock signal having been restored by the clock restoration circuit.

This arrangement, which is an embodiment of the first logic circuit, makes it possible to easily obtain the first or second separation means and easily realize the logic circuit of the present invention, which is adopted as the receiving logic circuit.

Further, the fourth logic circuit of the present invention, adopted as the receiving logic circuit, is characterized in that, the second separation means includes: a clock restoration circuit which restores the clock signal from the multivalued logic signal, in accordance with signal strength; a plurality of logical value restoration circuits each restoring, in accordance with signal strength, a logical value of a predetermined logic data signal from the multivalued logic signal so as to generate a logical value restoration data signal, the number of the logical value restoration circuits corresponding to the number of logical data signals having been synthesized; and latch circuits each latching the logical value restoration data signal by means of the clock signal having been restored by the clock restoration circuit.

This arrangement, which is an embodiment of the second separation means, makes it possible to easily obtain the second separation means and easily realize the logic circuit of the present invention, which is adopted as the receiving logic circuit.

Further, the third and fourth logic circuits, adopted as the receiving logic circuits, are characterized in that, the separation means further includes a delay circuit which causes a signal edge of the clock signal, which is restored by the clock restoration circuit, not to overlap a signal edge of the logical value restoration data signal.

When the edge of the restored clock signal is overlapped with the edge of the logical value restoration data signal whose logical value is restored, the risk of logical malfunction in the latch circuit increases. Thus, the delay circuit is provided so that the edge of the restored clock signal and the edge of the logical value restoration data signal are caused not to be overlapped with each other. With this arrangement, it is possible to eliminate the logical malfunction in the latch circuit.

In this case, the delay circuit is preferably provided either on the output side of the clock restoration circuit or on the output side of the logical value restoration circuit.

When the delay circuit is provided on the input side of the clock restoration circuit or on the input side of the logical value restoration circuit, the multivalued logic signal itself is delayed so that the delay circuit is necessarily an analog circuit. In contrast, when the delay circuit is provided on the output side of the clock restoration circuit or on the output side of the logical value restoration circuit, the logic data signal or H/L clock signal is delayed so that a typical delay circuit can be adopted.

As described above, the signal transmission system of the present invention includes the first or second logic circuit which is the sending logic circuit, and the third or fourth logic circuit which is the receiving logic circuit.

As in the foregoing description, according to this arrangement, the clock signal and logic data signal are synthesized and transmitted through a single transmission line. Thus, it is possible to eliminate the timing difference between the clock signal and logic data signal, which is caused due to such a reason that the clock signal and logic data signal are transmitted through different transmission paths.

On this account, it is possible to eliminate the constraint of a setup/hold period in a receiving end without including complicated synchronizing circuits such as a PLL circuit in the logic circuit of the receiving end, and this makes it possible to accommodate to further speedup of a clock signal in future and elongation of a transmission path.

As described above, the liquid crystal drive device of the present invention is arranged in such a manner that, the first or second logic circuit of the present invention, which is the sending logic circuit, is adopted as a control circuit, and the third or fourth logic circuit, which is the receiving logic circuit, is adopted as a source driver circuit.

Drive frequencies of liquid crystal drive devices are on the rise due to the increase of the size of liquid crystal panels. Further, in response to requirements such as narrowing the frame, aspect ratios of semiconductor devices such as a source driver circuit constituting a liquid crystal device further increase, while transmission lines connecting semiconductor devices also get longer.

Thus, adopting the signal transmission system using the logic circuits of the present invention which realize the above-described signal transmission method of the present invention, it is possible to realize an excellent liquid crystal drive device which can accommodate to speedup of a clock signal and elongation of a transmission path which are due to the increase of the sizes of liquid crystal panels.

Further, the liquid crystal drive device of the present invention is characterized in that a clock signal is synthesized with a digital display data signal.

Since the digital display data is a signal which varies more quickly than control signals which are logic data signals such as a start pulse and a latch strobe signal, the constraint of a setup/hold period is severe so that designing the timing becomes difficult as the speedup of a drive frequency and the elongation of a transmission line further proceed. For this reason, it is preferable to synthesize the digital display data with the clock signal.

In this case, it is particularly preferable that the first or second synthesizing means on the side of the control circuit and the first or second separation means on the side of the source driver circuit are provided so as to correspond to respective one or more digital display data signal(s) to be synthesized, in order to cause respective circuit arrangements regarding the digital display data signal(s) to be uniform.

The invention being thus described, it will be obvious that the same way may be varied in many ways. Such variations are not to be regarded as a departure from the spirit and scope of the invention, and all such modifications as would be obvious to one skilled in the art are intended to be included within the scope of the following claims.

What is claimed is:

1. A signal transmission method, wherein, when a logic data signal in sync with a clock signal is transmitted from a logic circuit to another logic circuit, in a sending end, a multivalued logic signal is synthesized from the clock signal and the logic data signal and outputted, and in a receiving end, the multivalued logic signal is separated into the clock signal and the logic data signal.

2. A logic circuit for transmitting one clock signal and one or more logic data signal(s) in sync with said one clock signal from a logic circuit to another logic circuit, comprising:
at least one synthesizing means for synthesizing said one clock signal with said one or more logic data signal(s) so as to produce one multivalued logic signal.

3. The logic circuit as defined in claim 2, wherein, said one or more logic data signal(s) include at least one fast logic data signal(s) and at least one slow logic data signal(s), and said at least one synthesizing means synthesizes said at least one fast logic data signal(s) with said one clock signal.

4. The logic circuit as defined in claim 2, wherein, said one or more logic data signal(s) include at least one logic data signal(s) transmitted via a long transmission path and at least one logic data signal(s) transmitted via a short transmission path, and said at least one synthesizing means synthesizes said at least one logic data signal transmitted via the long transmission path with said one clock signal.

5. The logic circuit as defined in claim 2, wherein, said one or more logic data signal(s) include a plurality of homogeneous logic data signals, and said at least one synthesizing means are provided so as to correspond to said one or more logic data signal(s) to be synthesized, in order to cause respective circuit arrangements regarding said plurality of homogeneous logic data signals to be uniform.

6. The logic circuit as defined in claim 2, wherein,
said at least one synthesizing means includes:
a plurality of signal strength sources having different signal strengths; and
a plurality of switches provided between said plurality of signal strength sources and an output section which outputs said one multivalued logic signal, and
said plurality of switches are controlled by said one or more logic data signal(s) and said one clock signal, which are to be synthesized.

7. The logic circuit as defined in claim 2, wherein, said one multivalued logic signal produced by said at least one synthesizing means is a voltage signal.

8. The logic circuit as defined in claim 2, wherein, said one multivalued logic signal produced by said at least one synthesizing means is a current signal.

9. A logic circuit, comprising:
at least one separation means for separating a multivalued logic signal, which is produced by synthesizing one clock signal with one or more logic data signal(s) in sync with said one clock signal and is transmitted from another logic circuit, into said one clock signal and said one or more logic data signal(s).

10. The logic circuit as defined in claim 9, wherein, in accordance with signal strength, said at least one separation means separate said one clock signal from the multivalued logic signal, restore a logical value(s) of said one or more logic data signal(s), and restore waveforms of said one or more logic data signal(s) from said logical value(s), using said one clock signal having been separated.

11. The logic circuit as defined in claim 9, wherein, the multivalued logic signal separated by said at least one separation means is a voltage signal.

12. The logic circuit as defined in claim 9, wherein, the multivalued logic signal separated by said at least one separation means is a current signal.

13. The logic circuit as defined in claim 9, wherein:
said at least one separation means includes one clock restoration circuit, one or more logical value restoration circuit(s), and one or more latch circuit(s), a number of said one or more logical value restoration circuit(s) and a number of said one or more latch circuit(s) corresponding to a number of said one or more logic data signal(s) having been synthesized;
said one clock restoration circuit restores said one clock signal from the multivalued logic signal, in accordance with signal strength;
said one or more logical value restoration circuit(s) restore logical values of said one or more logic data signal(s) from the multivalued logic signal, in accordance with signal strength, so as to generate a logical value restoration data signals; and
said one or more latch circuit(s) latch the logical value restoration data signal(s) by means of said one clock signal having been restored by said one clock restoration circuit.

14. The logic circuit as defined in claim 13, wherein, each of said at least one separation means further includes a delay circuit which causes a signal edge of said one clock signal, which is restored by said one clock restoration circuit, not to overlap a signal edge of the logical value restoration data signal.

15. The logic circuit as defined in claim 14, wherein, the delay circuit is provided either on an output side of said one clock restoration circuit or an output side of said one or more logical value restoration circuit(s).

16. A signal transmission system, comprising:
a sending logic circuit for transmitting one clock signal and one or more logic data signal(s) in sync with said one clock signal, the sending logic circuit including at least one synthesizing means which synthesizes said one clock signal with said one or more logic data signal(s) in sync with said one clock signal so as to produce one multivalued logic signal; and
a receiving logic circuit for receiving said one multivalued logic signal from the sending logic circuit, the receiving logic circuit including at least one separation means which separates said one multivalued logic signal having been received into said one clock signal and said one or more logic data signal(s).

17. A liquid crystal drive device, comprising:
a control circuit for outputting at least one control signal(s) including a clock signal and at least one digital display data signal(s); and
a source driver circuit for receiving said at least one control signal(s) and the digital display data signal which have been outputted from the control circuit,
wherein, the control circuit includes at least one synthesizing means which synthesizes one clock signal with one or more logic data signal(s) in sync with said one clock signal so as to produce one multivalued logic signal, and the source driver circuit includes at least one separation means which separates said one multivalued logic signal having been received from the control circuit into said one clock signal and said one or more logic data signal(s).

18. The liquid crystal drive device as defined in claim 17, wherein, said one or more logic data signal(s) to be synthesized for producing said one multivalued logic signal is said at least one digital display data signal(s).

19. The liquid crystal drive device as defined in claim 18, wherein, said at least one synthesizing means of the control circuit and said at least one separation means of the source driver circuit are provided so as to correspond to said at least one digital display data signal(s) to be synthesized, in order to cause respective circuit arrangements regarding said at least one digital display data signal(s) to be uniform.
